(19) United States
(12) Patent Application Publication
(10) Pub. No.: US 2026/0003196 A1
(43) Pub. Date: Jan. 1, 2026

(54) VIRTUAL IMAGE DISPLAY DEVICE AND OPTICAL UNIT

(71) Applicant: SEIKO EPSON CORPORATION, Tokyo (JP)

(72) Inventors: Yuiga HAMADE, MATSUMOTO-SHI (JP); Takashi TAKEDA, SUWA-SHI (JP)

(73) Assignee: SEIKO EPSON CORPORATION, Tokyo (JP)

(21) Appl. No.: 19/248,510

(22) Filed: Jun. 25, 2025

(30) Foreign Application Priority Data
Jun. 26, 2024 (JP) 2024-102742

(51) Int. Cl. G02B 27/01; G02F 1/1335; G02F 1/13363; G02F 1/1347; H10K 59/35

(52) U.S. Cl. CPC G02B 27/0172; G02F 1/133504; G02F 1/133526; G02F 1/13471; H10K 59/353; G02B 2027/0112; G02B 2027/0178; G02F 1/133638; G02F 2201/44

(57) ABSTRACT

A virtual image display device includes: a transmissive OLED panel configured to transmit external light in a first state and emit backlight in a second state, a display member of a transmissive type facing the transmissive OLED panel, and configured to further transmit the external light passed through the transmissive OLED panel in the first state and transmit the backlight emitted from the transmissive OLED panel in the second state to emit image light, and an imaging optical system facing the transmissive OLED panel with the display member in between, and configured to transmit at least part of the external light in the first state and form an image with the image light in the second state. The transmissive OLED panel includes a first transmissive OLED element configured to emit light of a first color, and a second transmissive OLED element configured to emit light of a second color.

The present application is based on, and claims priority from JP Application Serial Number 2024-102742, filed Jun. 26, 2024, the disclosure of which is hereby incorporated by reference herein in its entirety.

### BACKGROUND

### 1. Technical Field

The present disclosure relates to a virtual image display device and an optical unit that enable observation of a virtual image, and more particularly relates to a virtual image display device and the like and an optical unit using a transmissive OLED panel and a transmissive liquid crystal panel.

### 2. Related Art

As a see-through type virtual image display device that enables visual recognition of an outside world, a virtual image display device is known that includes a liquid crystal panel including an image display region and a transparent display region formed surrounding this image display region, and a light-guiding plate that guides backlight incident from a light source on an end portion, and in which the light-guiding plate includes a light emitting region that irradiates the image display region of the liquid crystal panel with the backlight, and a light transmitting region configured to transmit ambient light (WO 2016/056298). This virtual image display device is configured such that ambient light reaches the observer from the light transmitting region of the light-guiding plate and the transparent display region of the liquid crystal panel, and the ambient light passes through the light emitting region of the light-guiding plate and the image display region of the liquid crystal panel and reaches the observer in a period in which the image display region is not irradiated with the backlight. Such a configuration achieves see-through display in which image light and ambient light are overlapped on each other.

In the above-described device, processes such as formation of dots and application of a scattering material are performed on the light emitting region of the light-guiding plate, and the ambient light passing through the image display region of the liquid crystal panel passes through the processed light emitting region, and therefore see-through transmittance decreases in a vicinity of a center of a field of view corresponding to the image display region. In order to achieve see-through display with high see-through transmittance in the vicinity of the center of the field of view, an optical system or the like with high see-through transmittance is separately required, which leads to an increase in size.

### SUMMARY

A virtual image display device according to one aspect of the present disclosure includes: a transmissive organic light emitting diode (OLED) panel configured to transmit external light in a first state and emit backlight in a second state, a display element of a transmissive type facing the transmissive OLED panel, and configured to further transmit the external light passed through the transmissive OLED panel in the first state and transmit the backlight emitted from the transmissive OLED panel in the second state to emit image light, and an imaging optical system facing the transmissive OLED panel with the display element in between, and configured to transmit at least part of the external light in the first state and form an image with the image light in the second state, in which the transmissive OLED panel includes a first transmissive OLED element configured to emit light of a first color, and a second transmissive OLED element stacked on the first transmissive OLED element and configured to emit light of a second color.

An optical unit according to one aspect of the present disclosure includes: a transmissive OLED panel configured to transmit external light in a first state and emit backlight in a second state, a display element of a transmissive type facing the transmissive OLED panel, and configured to further transmit the external light passed through the transmissive OLED panel in the first state and transmit the backlight emitted from the transmissive OLED panel in the second state to emit image light, and an imaging optical system facing the transmissive OLED panel with the display element in between, and configured to transmit at least part of the external light in the first state and form an image with the image light in the second state, in which the transmissive OLED panel includes a first transmissive OLED element configured to emit light of a first color, and a second transmissive OLED element stacked on the first transmissive OLED element and configured to emit light of a second color.

### BRIEF DESCRIPTION OF THE DRAWINGS

FIG. 1 is an external front view illustrating a mounted state of a virtual image display device of a first embodiment.

FIG. 2 is a conceptual perspective view illustrating a structure of a display optical system.

FIG. 3 is a side cross-sectional view illustrating a light source member.

FIG. 4 is a side cross-sectional view illustrating a display.

FIG. 5 is a view illustrating a state of light passing through the display.

FIG. 6 is a side cross-sectional view illustrating an optical unit of the display optical system.

FIG. 7 is a view of the optical unit as viewed from another direction.

FIG. 8 is a conceptual perspective view illustrating a function of a polarization diffraction lens.

FIG. 9 is a timing chart showing a display operation by the display optical system.

FIG. 10 is a conceptual perspective view illustrating a transmissive liquid crystal panel of a second embodiment.

FIG. 11 is a side cross-sectional view illustrating the optical unit of the display optical system.

FIG. 12 is a front view and a cross-sectional view illustrating a positional relationship and dimensions of the transmissive liquid crystal panel.

FIG. 13 is a cross-sectional view illustrating a positional relationship between the transmissive liquid crystal panel and a spacer.

FIG. 14 is a side cross-sectional view illustrating an optical unit of a display optical system in a modification.

FIG. 15 is a side cross-sectional view illustrating a display of a third embodiment.

FIG. 16 is a view illustrating a state of light passing through the display.

FIG. 17 is a timing chart showing a display operation by the display optical system.

FIG. 18 is a side cross-sectional view illustrating a light source member in a modification.

### DESCRIPTION OF EMBODIMENTS

### First Embodiment

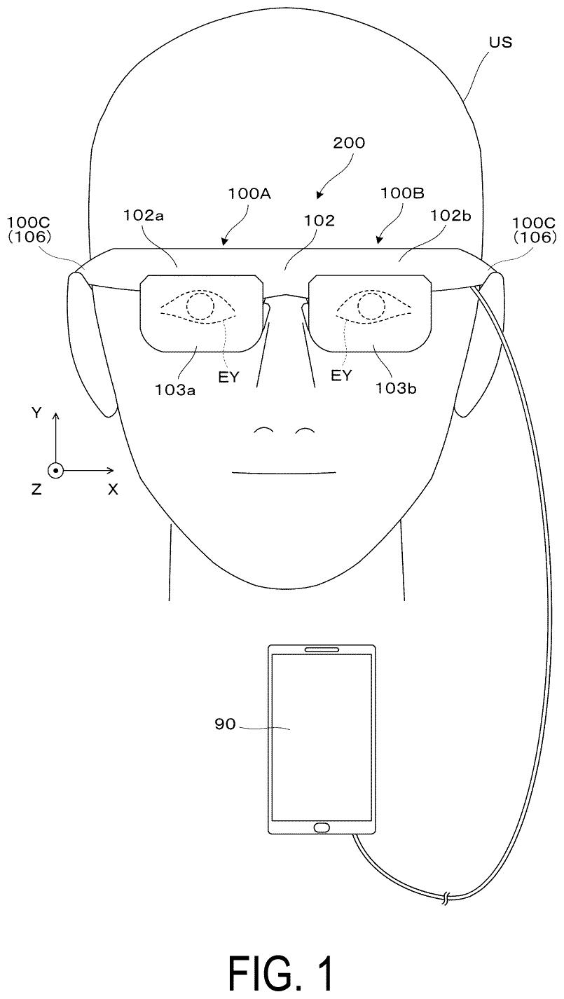

Hereinafter, a virtual image display device according to the first embodiment of the present disclosure will be described with reference to FIGS. 1 to 9.

FIG. 1 is a front view illustrating a mounted state of a head-mounted display, that is, a head-mounted display apparatus 200. The head-mounted display apparatus (hereinafter, also referred to as an HMD) 200 allows an observer or a wearer US who wears the HMD 200 to recognize an image as a virtual image. In FIG. 1 and the like, X, Y, and Z represent a Cartesian coordinate system. The +X direction corresponds to a lateral direction in which both eyes EY of the observer or the wearer US, who wears the HMD 200, are arranged. The +Y direction corresponds to an upper direction orthogonal to the lateral direction in which the both eyes EY are arranged for the wearer US. The +Z direction corresponds to a forward direction or a front side direction for the wearer US. The ±Y direction is parallel to a vertical axis or a vertical direction.

The HMD 200 includes a first virtual image display device 100A for a right eye, a second virtual image display device 100B for a left eye, a pair of temples 100C supporting the virtual image display devices 100A and 100B, and a user terminal 90 being an information terminal. The first virtual image display device 100A is configured with a first display driving unit 102a arranged in an upper portion and a first display optical system 103a covering in front of the eyes. The second virtual image display device 100B is configured with a second display driving unit 102b arranged in an upper portion and a second display optical system 103b covering in front of the eyes. The HMD 200 in which the first virtual image display device 100A and the second virtual image display device 100B are combined is also a virtual image display device in a broader sense. The pair of temples 100 C is a mounting member or a support device 106 mounted to the head part of the wearer US, and supports an upper end sides of the pair of display optical systems 103a and 103b via the display driving units 102a and 102b integrated in appearance. A combination of the pair of display driving units 102a and 102b is called a driving device 102.

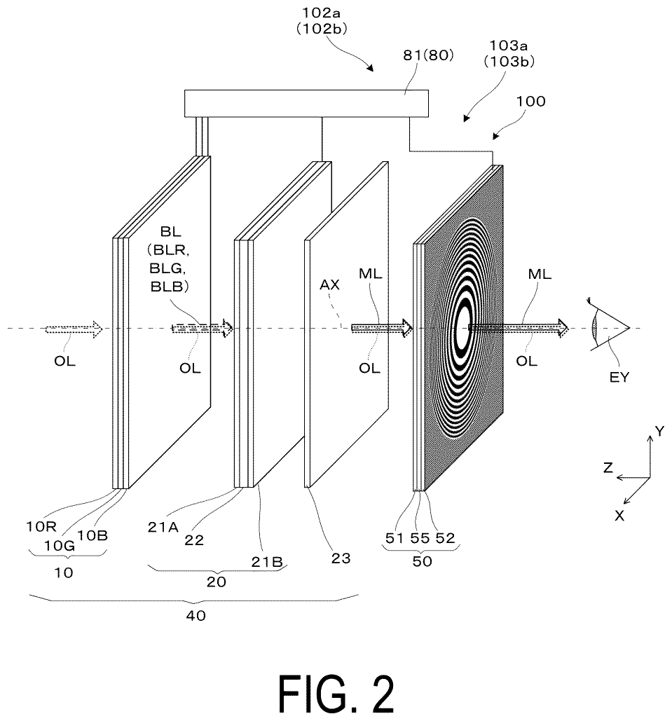

FIG. 2 is a conceptual perspective view illustrating a structure of the first display optical system 103a. The first display optical system 103a includes a display 40 having a plate shape that forms a two-dimensional image and emits image light ML corresponding to this, and an imaging optical system 50 having a plate shape configured to function as a lens for the image light ML emitted from the display 40 and forms a virtual image. In FIG. 2, for more easily understanding the configuration of the first display optical system 103a, an interval between the components is partially enlarged and illustrated.

The display 40 includes a light source member 10 including a first light source 10R that generates light of a first color, a second light source 10G that generates light of a second color, and a third light source 10B that generates light of a third color, a display element 20 that forms and emits the image light ML, and a quarter wavelength plate 23. The light source member 10 emits, as the backlight BL, backlight BLR of the first color, backlight BLG of the second color, and backlight BLB of the third color. The first color, the second color, and the third color are selected so as to be white light when the backlights BLR, BLG, and BLB are overlapped. The display 40 is driven and operated by a driving circuit 81 of a control device 80 incorporated in the first display driving unit 102a or the driving device 102. The display element 20 of the display 40 is arranged in proximity to the eye EY with the imaging optical system 50 in between, and enables observation of a virtual image by the image light ML and see-through viewing of the outside world. In the first display optical system 103a, the distance in an optical axis AX direction between the eye EY and the imaging optical system 50 is, for example, about 10 mm to 20 mm. The distance in the optical axis AX direction between a transmissive liquid crystal panel 22 of the display 40 and the imaging optical system 50 is, for example, about 5 mm to 25 mm.

The display element 20 is a plate-like member extending along an XY plane perpendicular to the optical axis AX, and includes a first polarization plate 21A, the transmissive liquid crystal panel 22, and a second polarization plate 21B in order from the outside. The display element 20 has a structure in which a stack of the polarization plates 21A and 21B and the transmissive liquid crystal panel 22 is integrated by a frame body not illustrated. Here, the first polarization plate 21A and the transmissive liquid crystal panel 22 are arranged in a vicinity of a predetermined interval or less. The transmissive liquid crystal panel 22 and the second polarization plate 21B are arranged in a vicinity of a predetermined interval or less. The transmissive liquid crystal panel 22 is an imager that forms first image light of a first color component, second image light of a second color component, and third image light of a third color component constituting the image light ML in time-division. Note that the transmissive liquid crystal panel 22 includes a plurality of pixels arrayed in a matrix along the XY plane.

The imaging optical system 50 is arranged on a face side, that is, the −Z side with respect to the display 40 or the display element 20 and covers the front of the eye. The imaging optical system 50 is a plate-like member extending along the XY plane, and includes a first polarization diffraction lens 51, a switching half-wavelength plate 55, and a second polarization diffraction lens 52 in order from the outside. The imaging optical system 50 has a structure in which optical elements constituting the imaging optical system 50, that is, the first polarization diffraction lens 51, the switching half-wavelength plate 55, and the second polarization diffraction lens 52 are arranged in a vicinity in a state of being parallel to one another, and these are integrated by a frame body not illustrated. Such integration enables the optical performance of the imaging optical system 50 to be stabilized, and the imaging optical system 50 to be thinned. Note that including a case where another optical element in addition to the switching half-wavelength plate 55 is arranged between the first polarization diffraction lens 51 and the second polarization diffraction lens 52, these can be integrated by directly fixing them via an adhesive, or can be integrated by fixing them on the outer periphery by bringing them into close contact with each other. The interval between the first polarization diffraction lens 51 and the second polarization diffraction lens 52 can be adjusted before integration. The imaging optical system 50 is a dynamic optical element having different actions depending on the state of the switching half-wavelength plate 55. The imaging optical system 50 functions as a lens for the image light ML emitted from the display element 20. That is, the imaging optical system 50 comprehensively forms an image with a plurality of pixels included in the transmissive liquid crystal panel 22, and enables an image formed on the transmissive liquid crystal panel 22 to be observed as a virtual image. On the other hand, the imaging optical system 50 functions as a parallel plate with respect to external light OL passing through the display element 20. That is, the external light OL is observed as a direct view image by being transmitted through the display element 20 so as to travel straight.

The second display optical system 103b is optically the same as the first display optical system 103a, or is obtained by inverting the first display optical system 103a horizontally. Thus, detail description thereof is omitted.

Note that in first virtual image display device 100A, an optical device excluding the control device 80 is called an optical unit 100. In the second virtual image display device 100B, an optical device excluding the control device 80 is called the optical unit 100.

The quarter wavelength plate 23 has a main axis in the middle between the X direction and the Y direction, for example, and converts the image light ML and the external light OL from linear polarization to circular polarization. Here, the image light ML being circular polarization means that when attention is paid to vibration of an electric field component or a magnetic field component of the image light ML, the vibration direction rotates at a frequency of the image light ML in a plane perpendicular to the traveling direction of the light, and an amplitude is constant regardless of the orientation. Clockwise circular polarization means that the vibration direction of the electric field component rotates clockwise as viewed from the observer standing facing the direction in which a beam advances, and counterclockwise circular polarization means that the vibration direction of the electric field component rotates counterclockwise. However, in the present description, as long as the image light ML mainly includes clockwise circular polarization, for example, even if linear polarization in a specific direction is included, such the image light ML is assumed to be clockwise circular polarization RCP. Similarly, as long as the image light ML mainly includes counterclockwise circular polarization, such the image light ML is assumed to be counterclockwise circular polarization LCP. In the present description, the clockwise circular polarization RCP is also called right circular polarization RCP, and the counterclockwise circular polarization LCP is also called left circular polarization LCP.

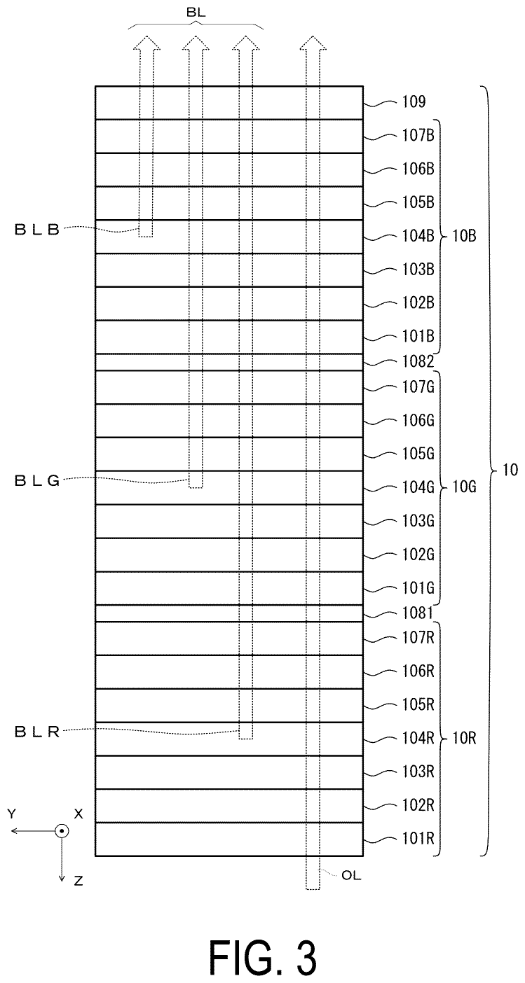

FIG. 3 is a side cross-sectional view illustrating the light source member 10 as a transmissive OLED panel. The first light source 10R, a first adhesive layer 1081, the second light source 10G, a second adhesive layer 1082, the third light source 10B, and a cover member 109 included in the light source member 10 of FIG. 3 are stacked in this order in the −Z direction in the Cartesian coordinate system. As illustrated in FIG. 2, the −Z direction is a direction in which the external light OL is incident on the light source member 10 from the outside, passes through the light source member 10, and then travels toward the display element 20, the imaging optical system 50, and the both eyes EY of the wearer US.

In the example of FIG. 3, the first light source 10R includes the first transmissive OLED element configured to emit the first backlight BLR as light of the first color. A first transparent substrate 101R, a first transparent anode 102R, a first hole transport layer 103R, a first light-emitting layer 104R, a first electron transport layer 105R, a first transparent cathode 106R, and a first sealing layer 107R included in the first transmissive OLED element are stacked in this order in the −Z direction in the Cartesian coordinate system.

When an appropriate voltage is applied between the first transparent anode 102R and the first transparent cathode 106R, the first transmissive OLED element emits, as the first backlight BLR, light of the first color from the first light-emitting layer 104R. A first wavelength included in the first backlight BLR corresponds to red, for example, and may be included in the range of 600 nm to 640 nm, and more preferably, may be included in the range of 610 nm to 630 nm.

Similarly, the second light source 10G includes the second transmissive OLED element configured to emit the second backlight BLG as light of the second color. A second transparent substrate 101G, a second transparent anode 102G, a second hole transport layer 103G, a second light-emitting layer 104G, a second electron transport layer 105G, a second transparent cathode 106G, and a second sealing layer 107G included in the second transmissive OLED element are stacked in this order in the −Z direction in the Cartesian coordinate system.

When an appropriate voltage is applied between the second transparent anode 102G and the second transparent cathode 106G, the second transmissive OLED element emits, as the second backlight BLG, light of the second color from the second light-emitting layer 104G. A second wavelength included in the second backlight BLG corresponds to green, for example, and may be included in the range of 500 nm to 550 nm, and more preferably, may be included in the range of 520 nm to 540 nm.

Furthermore, the third light source 10B includes a third transmissive OLED element configured to emit the third backlight BLB as light of the third color. A third transparent substrate 101B, a third transparent anode 102B, a third hole transport layer 103B, a third light-emitting layer 104B, a third electron transport layer 105B, a third transparent cathode 106B, and a third sealing layer 107B included in the third transmissive OLED element are stacked in this order in the −Z direction in the Cartesian coordinate system.

When an appropriate voltage is applied between the third transparent anode 102B and the third transparent cathode 106B, the third transmissive OLED element emits, as the third backlight BLB, light of the third color from the third light-emitting layer 104B. The third wavelength included in the third backlight BLB corresponds to blue, for example, and may be included in the range of 450 nm to 480 nm, and more preferably, may be included in the range of 450 nm to 460 nm.

Each of the first light-emitting layer 104R, the second light-emitting layer 104G, and the third light-emitting layer 104B may include a single light-emitting element, or may have a plurality of light-emitting elements arranged in a mesh shape on the XY plane. In the present embodiment, a configuration when each of the light-emitting layers 104R, 104G, and 104B has a single light-emitting element will be described.

The first transmissive OLED element, the second transmissive OLED element, and the third transmissive OLED element are glued and integrated by an adhesive such as resin. More specifically, the first adhesive layer 1081 is provided between the first sealing layer 107R of the first transmissive OLED element and the second transparent substrate 101G of the second transmissive OLED element, and an adhesive of the first adhesive layer 1081 is filled between the +Z direction side surface of the first sealing layer 107R and the −Z direction side surface of the second transparent substrate 101G. Similarly, the second adhesive layer 1082 is provided between the second sealing layer 107G of the second transmissive OLED element and the third transparent substrate 101B of the third transmissive OLED element, and an adhesive of the second adhesive layer 1082 is filled between the +Z direction side surface of the second sealing layer 107G and the −Z direction side surface of the third transparent substrate 101B. Filling the adhesive between the three transmissive OLED elements can give higher transmittance as a whole of the light source member 10 at least in a wavelength frequency band of visible light as compared with a case where an air layer is provided between the three transmissive OLED elements.

The +Z direction side surface of the third sealing layer 107B of the third transmissive OLED element is provided with the cover member 109 for protecting the third transmissive OLED element. On the other hand, since the second transmissive OLED element is glued to the +Z direction side surface of the first sealing layer 107R of the first transmissive OLED element, a cover member for protecting the first transmissive OLED element is omitted. Similarly, since the third transmissive OLED element is glued to the +Z direction side surface of the second sealing layer 107G of the second transmissive OLED element, a cover member for protecting the second transmissive OLED element is omitted. In this manner, integrating the three transmissive OLED elements can omit two cover members. As a result, the light source member 10 can be made thinner than that when the cover member is not omitted.

At least part of the first backlight BLR emitted from the first light-emitting layer 104R of the first light source 10R travels in the −Z direction, passes through the second light source 10G, the third light source 10B, and the cover member 109, and travels toward the display element 20, the imaging optical system 50, and the both eyes EY of the wearer US. Similarly, at least part of the second backlight BLG emitted from the second light-emitting layer 10G of the second light source 104G travels in the −Z direction, passes through the third light source 10B and the cover member 109, and travels toward the display element 20, the imaging optical system 50, and the both eyes EY of the wearer US. At least part of the third backlight BLB emitted from the third light-emitting layer 104B of the third light source 10B travels in the −Z direction, passes through the cover member 109, and travels toward the display element 20, the imaging optical system 50, and the both eyes EY of the wearer US. Note that another part of the first backlight BLR may travel in the +Z direction and leak out of the light source member 10. Similarly, another part of the second backlight BLG may travel in the +Z direction, pass through the first light source 10R, and leak out of the light source member 10. Another part of the third backlight BLB may travel in the +Z direction, pass through the second light source 10G and the first light source 10R, and leak out of the light source member 10. However, the light leaking out of the light source member 10 in this manner does not pass through the transmissive liquid crystal panel 22, and hence an image formed by the transmissive liquid crystal panel 22 does not leak out of the light source member 10.

In the example illustrated in FIG. 3, among the three transmissive OLED elements included in the light source member 10, the third transmissive OLED element configured to emit the third backlight BLB corresponding to blue is arranged at a position closest to the display element 20. Similarly, the first transmissive OLED element configured to emit the first backlight BLR corresponding to red is arranged at a position farthest from the display element 20, and the second transmissive OLED element configured to emit the second backlight BLG corresponding to green is arranged at an intermediate position. These arrangements are merely examples, and do not limit the present embodiment. However, the light-emitting layers 104R, 104G, and 104B as organic layers included in the OLED element are relatively easy to absorb light having a wavelength corresponding to blue. Therefore, each transmissive OLED element may be arranged such that light emitted from the third transmissive OLED element does not pass through the first transmissive OLED element and the second transmissive OLED element as much as possible. As an example, among the three transmissive OLED elements included in the light source member 10, the third transmissive OLED element may be arranged at a position closest to the display element 20.

In order to efficiently take out, to the outside of the light source member 10, the first backlight BLR, the second backlight BLG, and the third backlight BLB emitted by the respective transmissive OLED elements, the film thicknesses of the hole transport layers 103R, 103G, and 103B and the electron transport layers 105R, 105G, and 105B included in the light source member 10 may be set as follows. That is, the film thicknesses of the hole transport layers 103R, 103G, and 103B and the electron transport layers 105R, 105G, and 105B are made thicker in the first transmissive OLED element, thinner in the third transmissive OLED element, and intermediate in the second transmissive OLED element. As a more specific example, the thickness of the first hole transport layer 103R is set to 106 nm, the thickness of the second hole transport layer 103G is set to 75 nm, and the thickness of the third hole transport layer 103B is set to 50 nm. The thickness of the first electron transport layer 105R is set to 66 nm, the thickness of the second electron transport layer 105G is set to 48 nm, and the thickness of the third electron transport layer 105B is set to 33 nm. Here, the thickness of each of the first light-emitting layer 104R, the second light-emitting layer 104G, and the third light-emitting layer 104B is set to 30 nm. In this case, the total thickness of the first hole transport layer 103R, the first light-emitting layer 104R, and the first electron transport layer 105R is 202 nm. Similarly, the total thickness of the second hole transport layer 103G, the second light-emitting layer 104G, and the second electron transport layer 105G is 153 nm. The total thickness of the third hole transport layer 103B, the third light-emitting layer 104B, and the third electron transport layer 105B is 113 nm.

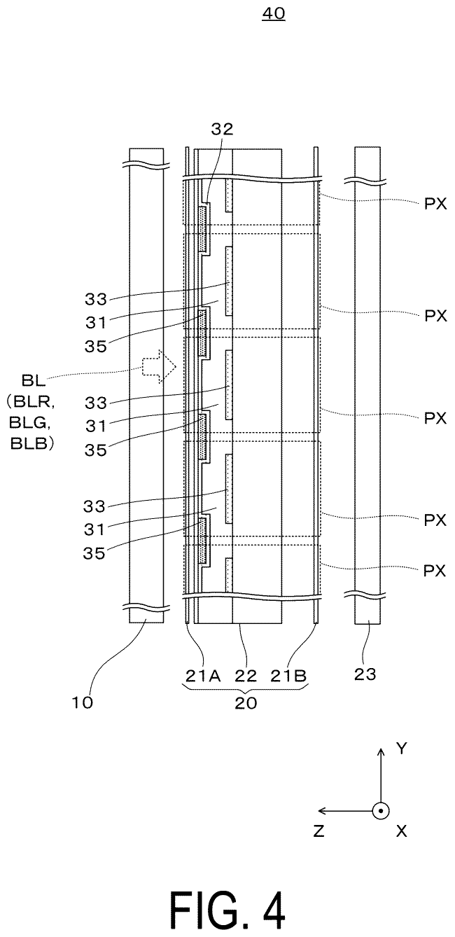

FIG. 4 is a conceptual enlarged cross-sectional view illustrating the structure of the display 40. With reference to FIG. 4, the light source member 10 generates, as the backlight BL, the backlights BLR, BLG, and BLB of three colors in time-division, and supplies any one of the backlights BLR, BLG, and BLB of three colors to the transmissive liquid crystal panel 22 of the display element 20 at a time.

The display element 20 is arranged on the face side, that is, the −Z side facing the light source member 10 and the first polarization plate 21A. The display element 20 includes the transmissive liquid crystal panel 22 and a pair of the polarization plates 21A and 21B sandwiching the transmissive liquid crystal panel 22. In this case, the display element 20 is a modulation element made of, for example, an inplane switching (IPS) liquid crystal, and operates in units of pixels PX. The pixel PX includes no filter and is colorless. The display element 20 does not rotate the polarization direction of incident light when no electric field is applied, and rotates the polarization direction of incident light when an electric field is applied. In this case, the pair of polarization plates 21A and 21B are absorption type polarization elements, and are arranged such that polarization directions intersect each other, more specifically, polarization directions are orthogonal to each other. The display element 20 can switch between ON and OFF in units of pixels PX according to a driving signal from the driving circuit 81, and can partially pass through incident light at an arbitrary gradation in between ON and OFF. Therefore, the transmissive liquid crystal panel 22 includes not only a liquid crystal layer 31, a common electrode 32, a pixel electrode 33, and a black matrix 35, but also a scanning line, a signal line, and a switching element not illustrated. The transmissive liquid crystal panel 22 may be produced as an high-temperature poly-silicon (HTPS) panel for higher definition.

Note that the display element 20 or the transmissive liquid crystal panel 22 may rotate the polarization direction of incident light when no electric field is applied, and needs not rotate the polarization direction of incident light when an electric field is applied. In this case, the pair of polarization plates 21A and 21B are arranged such that the polarization directions are parallel to each other.

The quarter wavelength plate 23 has a main axis in the middle between the X direction and the Y direction, for example, and converts the image light ML and the external light OL (see FIG. 2) from linear polarization to circular polarization. Here, the image light ML being circular polarization means that when attention is paid to vibration of an electric field component or a magnetic field component of the image light ML, the vibration direction rotates at a frequency of the image light ML in a plane perpendicular to the traveling direction of the light, and an amplitude is constant regardless of the orientation. Clockwise circular polarization means that the vibration direction of the electric field component rotates clockwise as viewed from the observer standing facing the direction in which a beam advances, and counterclockwise circular polarization means that the vibration direction of the electric field component rotates counterclockwise. However, in the present description, as long as the image light ML mainly includes clockwise circular polarization, for example, even if linear polarization in a specific direction is included, such the image light ML is assumed to be the clockwise circular polarization RCP. Similarly, as long as the image light ML mainly includes counterclockwise circular polarization, such the image light ML is assumed to be the counterclockwise circular polarization LCP. In the present description, the clockwise circular polarization RCP is also called the right circular polarization RCP, and the counterclockwise circular polarization LCP is also called the left circular polarization LCP.

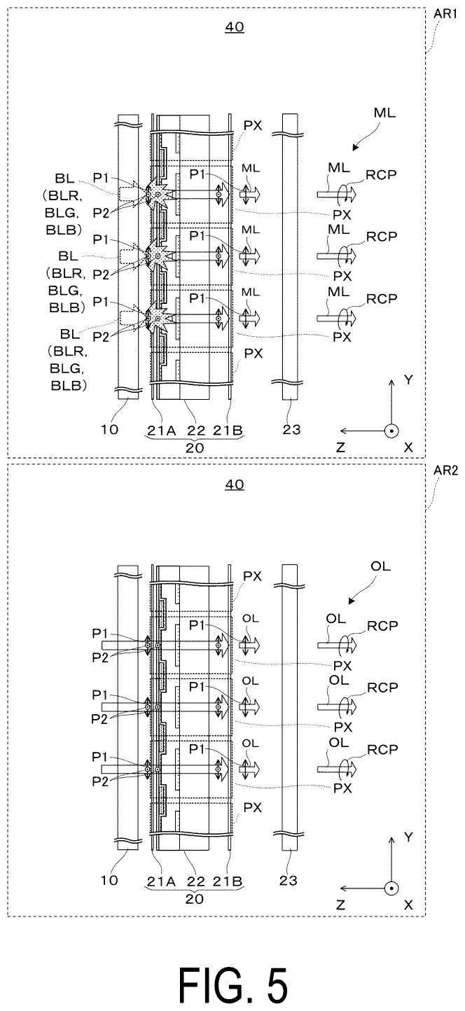

FIG. 5 is a view illustrating a state of light passing through the display 40. In FIG. 5, a first area AR1 indicates a case where the first display optical system 103a is in an image observation period and the display 40 is in a display state, and a second area AR2 indicates a case where the first display optical system 103a is in an outside light observation period and the display 40 is in a non-display state.

With reference to FIG. 5, when the display 40 is in the display state in the image observation period, any one of the light-emitting layers 104R, 104G, and 104B illustrated in FIG. 3 of the light source member 10 selectively emits light according to a control signal from the control device 80 illustrated in FIG. 2, and at least part of any one of BLR, BLG, and BLB of the backlight BL is emitted toward the display element 20. The backlight BL (BLR, BLG, and BLB) illuminates the transmissive liquid crystal panel 22 as second polarization P2 that is lateral polarization or horizontal polarization via the first polarization plate 21A of the display element 20. That is, each colorless pixel PX constituting the display element 20 is illuminated. The image light ML passed through the transmissive liquid crystal panel 22 is obtained by rotating a polarization plane of the backlight BL (BLR, BLG, and BLB) according to a driving signal, and only first polarization P1 that is longitudinal polarization or vertical polarization is emitted through the second polarization plate 21B. The image light ML emitted from each pixel PX of the display element 20 is converted from the first polarization P1 to the right circular polarization RCP through the quarter wavelength plate 23.

On the other hand, when the display 40 is in the non-display state in the outside light observation period, the light source member 10 is brought into a non-light emission state, that is, a light off state. At this timing, the external light OL is incident on the display element 20. At this time, each pixel PX of the display element 20 operates normally off, for example, and is brought into a maximum transmission state by the driving signal, and the second polarization P2 of the external light OL incident on each pixel PX of the display element 20 travels straight through the display element 20, that is, the pixel PX, and is converted into the first polarization P1. The external light OL emitted from each pixel PX of the display element 20 is converted from the first polarization P1 to the right circular polarization RCP through the quarter wavelength plate 23.

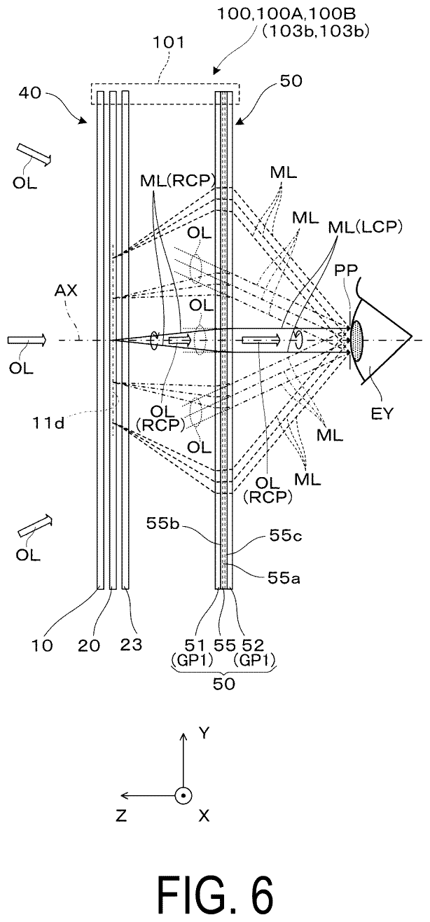

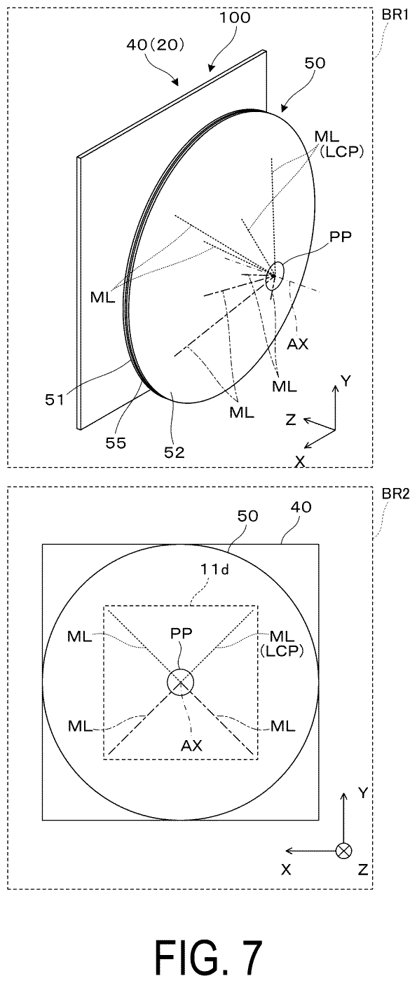

FIG. 6 is a side cross-sectional view illustrating the optical unit 100 of the display optical systems 103a and 103b, and FIG. 7 is a view of the optical unit 100 as viewed from another direction. In FIG. 7, a first region BR1 is a perspective view of the optical unit 100, and a second region BR2 is a back view of the optical unit 100.

The optical unit 100 includes the display 40 configured to emit the image light ML and transmit the external light OL, the imaging optical system 50 configured to function as a positive lens or a collimator having positive power with respect to the image light ML, and a support member 101 configured to relatively fix these components.

In the imaging optical system 50, the first polarization diffraction lens 51 functions as a positive lens alone when predetermined circular polarization is incident, and the second polarization diffraction lens 52 also functions as a positive lens alone when predetermined circular polarization is incident. The switching half-wavelength plate 55 can be switched between an ON state and an OFF state. When the switching half-wavelength plate 55 is in the ON state, both the polarization diffraction lenses 51 and 52 function as positive lenses, and when the switching half-wavelength plate 55 is in the OFF state, the power of the polarization diffraction lenses 51 and 52 is offset to function as a parallel plate glass.

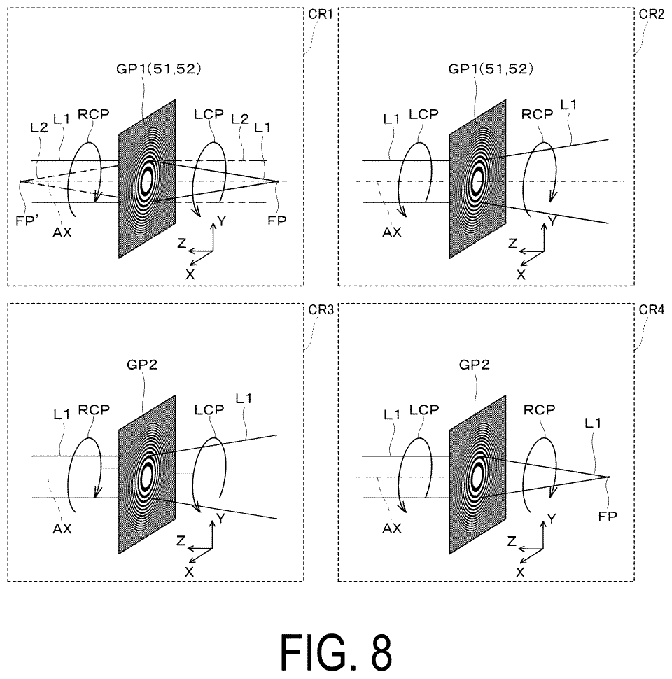

FIG. 8 is a conceptual perspective view illustrating functions of the first polarization diffraction lens 51 and the second polarization diffraction lens 52. In FIG. 8, a first region CR1 illustrates a first operation example of a polarization diffraction lens GP1 of a first type, and a second region CR2 illustrates a second operation example of the polarization diffraction lens GP1 of the first type. In FIG. 8, a third region CR3 illustrates a first operation example of a polarization diffraction lens GP2 of a second type, and a fourth region CR4 illustrates a second operation example of the polarization diffraction lens GP2 of the second type. The first polarization diffraction lens 51 and the second polarization diffraction lens 52 illustrated in FIG. 8 are the polarization diffraction lens GP1 of the first type.

The polarization diffraction lens GP1 has a function of converting the right circular polarization RCP into the left circular polarization LCP, converging the same, and condensing the same on a focal point FP when the right circular polarization RCP collimated such as a beam L1 indicated by the solid line from the left side of the drawing is incident, and has a function of converting the left circular polarization LCP into the right circular polarization RCP and diverging the same when the left circular polarization LCP collimated such as the beam L1 indicated by the solid line from the left side of the drawing is incident. Note that the polarization diffraction lens GP1 has a function of converting the right circular polarization RCP into the left circular polarization LCP and collimating the same when the right circular polarization RCP diverging from a focal point FP′ on the left side of the drawing such as a beam L2 indicated by the two-dot chain line is incident. That is, the polarization diffraction lens GP1 inverts the rotation direction of polarization while functioning as a positive lens having a predetermined focal length with respect to the right circular polarization RCP. The polarization diffraction lens GP1 inverts the rotation direction of polarization while functioning as a negative lens having a focal length with the same absolute value with respect to the left circular polarization LCP. That is, the polarization diffraction lens GP1 is an optical element having positive power with respect to the right circular polarization RCP and having negative power with respect to the left circular polarization LCP.

The polarization diffraction lens GP2 has a function of converting the right circular polarization RCP into the left circular polarization LCP and diverging the same when the right circular polarization RCP collimated such as a beam L1 indicated by the solid line from the left side of the drawing is incident. The polarization diffraction lens GP2 has a function of converting the left circular polarization LCP into the right circular polarization RCP, converging the same, and condensing the same on the focal point FP when the left circular polarization LCP collimated such as the beam L1 indicated by the solid line from the left side of the drawing is incident. That is, the polarization diffraction lens GP2 inverts the rotation direction of polarization while functioning as a positive lens having a predetermined focal length with respect to the left circular polarization LCP. The polarization diffraction lens GP2 inverts the rotation direction of polarization while functioning as a negative lens having a focal length with the same absolute value with respect to the right circular polarization RCP. That is, the polarization diffraction lens GP2 is an optical element having negative power with respect to the right circular polarization RCP and positive power with respect to the left circular polarization LCP.

In the polarization diffraction lenses GP1 and GP2, a distribution of refractive index anisotropy grasped in units of a large number of annular bands about the optical axis AX in a plane is formed, and the polarization diffraction lenses function as diffraction lenses according to the distribution of this refractive index anisotropy and the polarization state of the incident light. Specifically, in the polarization diffraction lenses GP1 and GP2, when the distribution of the refractive index anisotropy is provided such that the azimuth of the optical axis rotates with an increasing distance from the optical axis AX with respect to two directions orthogonal to the center optical axis AX and orthogonal to each other (actually repeats in the range of 0 to π), a geometric phase is formed in specific circular polarization incident on this, diffraction of the circular polarization occurs at a diffraction angle reflecting the cycle length of rotation of the optical axis with respect to each azimuth, and the polarization state is inverted. The entire polarization diffraction lens generates diffraction corresponding to the power formed by the lens shape for specific circular polarization, and inverts the state of the circular polarization from, for example, right circular polarization to left circular polarization before and after passing.

Although not illustrated, the polarization diffraction lens GP1 and the polarization diffraction lens GP2 are formed by forming a thin film liquid crystal containing material layer on a transparent substrate, and have a thin plate shape as a whole. The liquid crystal containing material layer contains a predetermined liquid crystal material, and alignment axes of liquid crystal molecules are aligned parallel to, for example, the X direction in a vicinity region to the optical axis AX so that a desired geometric phase is formed, and gradually rotate in the XY plane as the distance from the optical axis AX increases, that is, according to a distance or a radius about the optical axis AX. That is, the rotation angle of the alignment axis of the liquid crystal molecules increases according to the distance from the optical axis AX, and this is cyclically repeated. In a liquid crystal compound layer, in the Z direction parallel to the optical axis AX, for example, the alignment axes of the liquid crystal molecules are arrayed while being kept constant. Note that in the polarization diffraction lens GP1 and the polarization diffraction lens GP2, the direction of increasing the rotation angle of the alignment axis of the liquid crystal molecules is inverted. As a method for producing the polarization diffraction lens GP1 and the polarization diffraction lens GP2, for example, a liquid crystal containing material film in which a liquid crystal material and an ultraviolet curable organic material layer are mixed is applied onto a substrate, and UV laser light in a predetermined polarization state is two-dimensionally scanned with respect to the liquid crystal containing material film, thereby curing the organic material layer while adjusting the alignment axes of the liquid crystal molecules. This can three-dimensionally control and fix the alignment axes of the liquid crystal molecules in the liquid crystal containing material layer, and gives a liquid crystal compound layer in which the rotation angle of the alignment axis increases as the distance from the optical axis AX increases as described above. Such the polarization diffraction lens GP1 itself is a known technique (see, e.g., literature, Kohei Noda, et al., Applied Optics, Feb. 10, 2017, Vol. 56, No. 5: 1302) as a polarization dependent liquid crystal Fresnel lens, for example.

The polarization diffraction lens GP1 and the polarization diffraction lens GP2 do not need to be separate lenses, and when the polarization diffraction lens GP1 is rotated by 180° around the Y axis and its front and back are inverted, the polarization diffraction lens GP2 is obtained. That is, the polarization diffraction lenses GP1 and GP2 can function as both a positive lens and a negative lens for the same circular polarization by switching the front and back of the polarization diffraction lenses GP1 and GP2. The reason is that, in the polarization diffraction lenses GP1 and GP2, since the alignment axes of the liquid crystal molecules are increased so as to rotate in a specific direction according to the distance about the optical axis AX as described above, the rotation direction with respect to the absolute value of the distance coincides, for example, in the ±X direction perpendicular to the optical axis AX, and the rotation direction of the alignment axes is inverted when each of the polarization diffraction lenses GP1 and GP2 is viewed from the back side.

The focal length of the polarization diffraction lens GP1 and the focal length of the polarization diffraction lens GP2 can be increased or decreased depending on a manufacturing method or a liquid crystal material. In the liquid crystal compound layer, for example, by increasing the increase rate of the rotation angle with respect to the distance from the optical axis AX or the radius when increasing the rotation angle of the alignment axes of the liquid crystal molecules as the distance from the optical axis AX increases, that is, by decreasing the cycle length of the rotation of the alignment axes, the absolute value of the positive or negative power of the polarization diffraction lenses GP1 and GP2 can be increased, and the focal length can be adjusted. When passing through the polarization diffraction lenses GP1 and GP2, the loss of the beam L1 of the circular polarization is close to zero, and the polarization diffraction lenses GP1 and GP2 exhibit transmittance of almost 100%.

When linear polarization is incident on the polarization diffraction lens GP1, the behavior of the right circular polarization RCP and the behavior of the left circular polarization LCP included in the linear polarization are different from each other. A component of the right circular polarization RCP is condensed through the polarization diffraction lens GP1, a component of the left circular polarization LCP is diverged through the polarization diffraction lens GP1, and the rotation direction of each polarization is inverted.

Returning to FIG. 6, the switching half-wavelength plate 55 is a device configured to perform a switch type operation according to the driving signal from the driving circuit 81 illustrated in FIG. 2, and switches the polarization state of the incident light from the right circular polarization RCP to the left circular polarization LCP depending on the alignment direction of the liquid crystal and allows the incident light to pass therethrough, or allows the incident light to pass therethrough as the right circular polarization RCP as it is. That is, the switching half-wavelength plate 55 is switched between an ON state as a first state in which the image light ML passed through the first polarization diffraction lens 51 is returned from the left circular polarization LCP that is the second circular polarization to the right circular polarization RCP that is the first circular polarization and an OFF state as a second state in which the image light ML passed through the first polarization diffraction lens 51 is allowed to pass through as the left circular polarization LCP as it is that is the second circular polarization. The switching half-wavelength plate 55 includes a liquid crystal layer 55a sandwiched between a pair of base materials 55b and 55c with a transparent electrode layer not illustrated in between. The liquid crystal layer 55a is, for example, an inplane switching (IPS) type liquid crystal or the like, and causes the switching half-wavelength plate 55 to function as an optical element equivalent to a half-wavelength plate in which a main axis or a fast axis is set in a specific direction (e.g., in the middle between the X direction and the Y direction) when an electric field is applied, and causes the switching half-wavelength plate 55 to function as an isotropic parallel plate when no electric field is applied. The switching half-wavelength plate 55 switches between the ON state and the OFF state not in units of pixels but on the entire surface.

In the imaging optical system 50, the first polarization diffraction lens 51 is the polarization diffraction lens GP1 illustrated in FIG. 8, and when the image light ML and the external light OL incident from the display 40 are the right circular polarization RCP, functions as an optical element having positive power with respect to the image light ML and the external light OL, and inverts the rotation direction of the polarization to the left circular polarization LCP while reducing the divergence degree of the image light ML and the external light OL. The image light ML and the external light OL passed through the first polarization diffraction lens 51 are incident on the switching half-wavelength plate 55 in a state of being the left circular polarization LCP.

The switching half-wavelength plate 55 is in the ON state during the image observation period, that is, at the timing when the image light ML is incident, and is in the OFF state during the outside light observation period, that is, at the timing when the external light OL is incident.

During the image observation period, the switching half-wavelength plate 55 in the ON state converts the image light ML incident thereon from the left circular polarization LCP to the right circular polarization RCP, but allows the image light ML to pass therethrough without substantially giving a convergence action as a parallel plate, and causes the image light ML to be incident on the second polarization diffraction lens 52. The second polarization diffraction lens 52 is the polarization diffraction lens GP1 illustrated in FIG. 8, and when the image light ML passed through the switching half-wavelength plate 55 is the right circular polarization RCP, functions as an optical element having positive power with respect to the image light ML, and inverts the rotation direction of the polarization to the left circular polarization LCP while reducing the divergence degree of the image light ML. At this time, the absolute value of the power of the first polarization diffraction lens 51 and the absolute value of the power of the second polarization diffraction lens 52 are set to be equal to each other, and the combined focal length of the both polarization diffraction lenses 51 and 52 is substantially equivalent to the combined focal length of the two thin convex lenses arranged adjacent to each other. When the combined focal length of the both polarization diffraction lenses 51 and 52 is equal to the distance from a midpoint of the both polarization diffraction lenses 51 and 52 to a display surface 11d of the display 40, the imaging optical system 50 functions as a collimator and condenses the image light ML at a pupil position PP while collimating the image light ML. Although FIG. 5 illustrates only the main beam of the image light ML from the display surface 11d, it is understood that the image light ML from a diagonal position of the display surface 11d passes through the pupil position PP as illustrated in FIGS. 6 and 7.

On the other hand, in the outside light observation period, the switching half-wavelength plate 55 in the OFF state maintains the external light OL incident thereon as the left circular polarization LCP as it is, and causes the external light OL to be incident on the second polarization diffraction lens 52. The second polarization diffraction lens 52 is the polarization diffraction lens GP1 illustrated in FIG. 8, and when the external light OL passed through the switching half-wavelength plate 55 is the left circular polarization LCP, functions as an optical element having negative power with respect to the external light OL, and inverts the rotation direction of the polarization while reducing the convergence degree of the external light OL, thereby obtaining the right circular polarization RCP. At this time, the both polarization diffraction lenses 51 and 52 are arranged in the vicinity and are set so that the absolute values of power of them are equal, and the combined focal length of the both polarization diffraction lenses 51 and 52 is infinity. When the combined focal length of the polarization diffraction lenses 51 and 52 is infinite, the imaging optical system 50 functions as an equivalent to a parallel plate that is an optical system having substantially zero power, and can achieve a state in which the external light OL is observed with the naked eye by causing the external light OL to travel substantially straight without exerting an image forming action such as condensing on the external light OL.

As described above, in the image observation period, the imaging optical system 50 is brought into a state of having positive power by the switching half-wavelength plate 55 in the ON state, the image light ML can be observed, and in the outside light observation period, the imaging optical system 50 is in a state of substantially zero power by the switching half-wavelength plate 55 in the OFF state, and the external light OL can be observed. That is, the virtual image display devices 100A and 100B or the display optical systems 103a and 103b that perform such display enable see-through display in which the image light ML and the external light OL are overlapped in time-division.

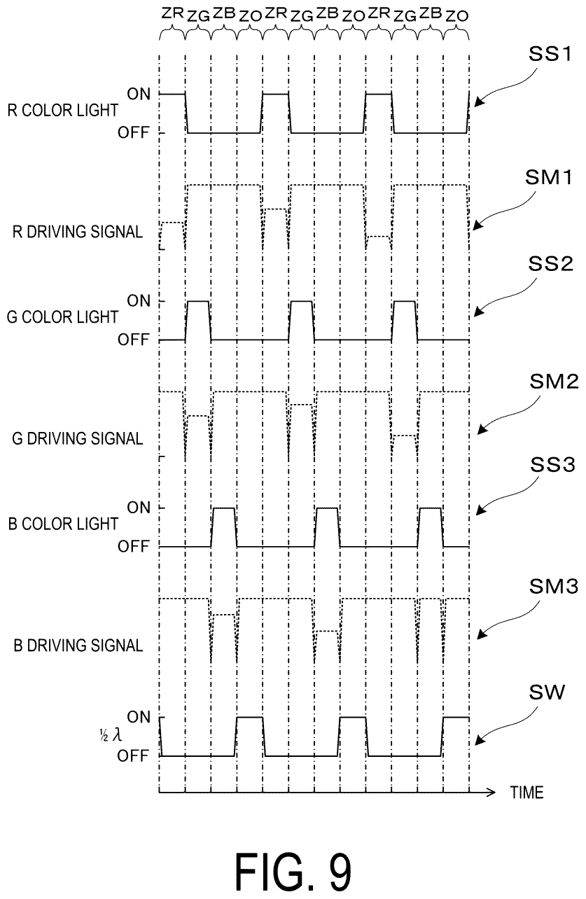

FIG. 9 is a timing chart showing the display operation by the display optical systems 103a and 103b. The horizontal axis indicates time, and a blinking signal SS1 of the first light source 10R of the first color (e.g., R, red), a first driving signal SM1 of first color component display given to the transmissive liquid crystal panel 22, a blinking signal SS2 of the second light source 10G of the second color (e.g., G, green), a second driving signal SM2 of second color component display given to the transmissive liquid crystal panel 22, a blinking signal SS3 of the third light source 10B of the third color (e.g., B, blue), a third driving signal SM3 of third color component display given to the transmissive liquid crystal panel 22, and an on-off signal SW of the switching half-wavelength plate (½λ) 55 are illustrated in order from the top. The operation of the first virtual image display device 100A includes, in each frame, a first sub-frame ZR, which is a first color image observation sub-frame, a second sub-frame ZG, which is a second color image observation sub-frame, a third sub-frame ZB, which is a third color image observation sub-frame, and a fourth sub-frame ZO, which is an outside light observation sub-frame. The driving circuit 81 of the control device 80 outputs the blinking signals SS1, SS2, and SS3 and controls the operations of the light sources 10R, 10G, and 10B, respectively, outputs the driving signals SM1, SM2, and SM3 and controls the operation of the transmissive liquid crystal panel 22, and outputs the on-off signal SW and controls the operation of the switching half-wavelength plate 55.

In this case, when the first virtual image display device 100A is in the first sub-frame ZR of the image observation period, the first light source 10R emits the backlight BLR of the first color, and the transmissive liquid crystal panel 22 is in the display state of the first color component, the first virtual image display device 100A displays first image light ML (R) representing the intensity distribution of the wavelength component of the first color of the image light ML. Similarly, when the first virtual image display device 100A is in the second sub-frame ZG of the image observation period, the second light source 10G emits the backlight BLG of the second color, and the transmissive liquid crystal panel 22 is in the display state of the second color component, the first virtual image display device 100A displays second image light ML (G) representing the intensity distribution of the wavelength component of the second color of the image light ML. When the first virtual image display device 100A is in the third sub-frame ZB of the image observation period, the third light source 10B emits the backlight BLB of the third color, and the transmissive liquid crystal panel 22 is in the display state of the third color component, the first virtual image display device 100A displays third image light ML (B) representing the intensity distribution of the wavelength component of the third color of the image light ML. In this manner, the first virtual image display device 100A displays the full-color image light ML by repeating, in a sufficiently short cycle, each state of the sub-frames ZR, ZG, and ZB of displaying, one by one in time-division, the image lights ML (R), ML (G), and ML (B) representing the intensity distribution of the wavelength components of the three colors included in the image light ML.

Note that in the first sub-frame ZR, the second light source 10G and the third light source 10B are in a transmission state of not emitting the backlights BLG and BLB and transmit the backlight BLR of the first color emitted by the first light source 10R, and the transmissive liquid crystal panel 22 forms only the first image light ML (R) of the image light ML and does not form the second image light ML (G) and the third image light ML (B), and therefore only the first image light ML (R) representing the intensity distribution of the wavelength component of the first color of the image light ML is displayed. Similarly, in the second sub-frame ZG, the first light source 10R is in the transmission state of not emitting the backlight BLR, the third light source 10B is in the transmission state of not emitting the backlight BLB and transmits the backlight BLG of the second color emitted by the second light source 10G, and the transmissive liquid crystal panel 22 forms only the second image light ML (G) of the image light ML and does not form the first image light ML (R) and the third image light ML (B), and therefore only the second image light ML (G) representing the intensity distribution of the wavelength component of the second color of the image light ML is displayed. In the third sub-frame ZB, the first light source 10R and the second light source 10G are in the transmission state of not emitting the backlights BLR and BLG, and the transmissive liquid crystal panel 22 forms only the third image light ML (B) of the image light ML and does not form the first image light ML (R) and the second image light ML (G), and therefore only the third image light ML (B) representing the intensity distribution of the wavelength component of the third color of the image light ML is displayed.

When the first virtual image display device 100A is in the fourth sub-frame ZO as the outside light observation period, the light sources 10R, 10G, and 10B are in the transmission state of not emitting the backlights BLR, BLG, and BLB, the transmissive liquid crystal panel 22 is in the non-display state, and the switching half-wavelength plate 55 is in the off state of transmitting light as it is, the external light OL passes through the light sources 10R, 10G, and 10B, the transmissive liquid crystal panel 22, and the switching half-wavelength plate 55, and reaches the eye EY of the wearer US. In this manner, the first virtual image display device 100A repeats, in a sufficiently short cycle, the state in which the first color component, the second color component, and the third color component of the image light ML are displayed in time-division in the image observation period including the sub-frames ZR, ZG, and ZB and the state in which the external light OL is transmitted in the outside light observation period as the sub-frame ZO, thereby enabling see-through display in which the full-color image light ML and the external light OL are overlapped in time-division.

The virtual image display devices 100A and 100B or the optical unit 100 according to the first embodiment described above include the light source member 10 as the transmissive OLED panel configured to transmit the external light OL in the first state and emit the backlight BL in the second state, the transmissive display element 20 arranged facing the transmissive OLED panel, and configured to further transmit the external light OL passed through the transmissive OLED panel in the first state and transmit the backlight BL emitted by the transmissive OLED panel in the second state to emit image light, the imaging optical system 50 arranged facing the transmissive OLED panel with the display element 20 in between, and configured to transmit at least part of the external light OL in the first state and form the image light in the second state, and the control device 80 configured to switch between the first state and the second state by controlling the transmissive OLED panel, the display element 20, and the imaging optical system 50, in which the transmissive OLED panel includes the third light source 10B as the first transmissive OLED element configured to emit the first backlight of the first color, and the second light source 10G as the second transmissive OLED element stacked on the third light source 10B as the first transmissive OLED element and configured to emit the second backlight of the second color.

The virtual image display devices 100A and 100B or the optical unit 100 uses the transmissive OLED panel as a surface emission source as the light source member 10 configured to generate the backlight BL. As a result, the virtual image display devices 100A and 100B or the optical unit 100 can uniformly turn on the backlight BL, and can suppress luminance unevenness of an image. Use of the transmissive OLED element can reduce the power consumption for generating the backlight BL, downsize the light source member 10, and achieve both high transmittance with respect to the external light OL and good display of the image light ML. Furthermore, in the virtual image display devices 100A and 100B or the optical unit 100, the first polarization diffraction lens 51 having positive power with respect to image light having the first circular polarization and the second polarization diffraction lens 52 having positive power with respect to image light having the second circular polarization after passing through the first polarization diffraction lens 51 are combined, thereby achieving the imaging optical system 50 having a relatively thin and a relatively short focal length.

### Second Embodiment

Hereinafter, virtual image display devices 100A and 100B and the like of the second embodiment will be described. Note that the virtual image display devices 100A and 100B of the second embodiment are obtained by partially changing the virtual image display devices 100A and 100B of the first embodiment, and description of parts common to the virtual image display devices 100A and 100B of the first embodiment will be omitted.

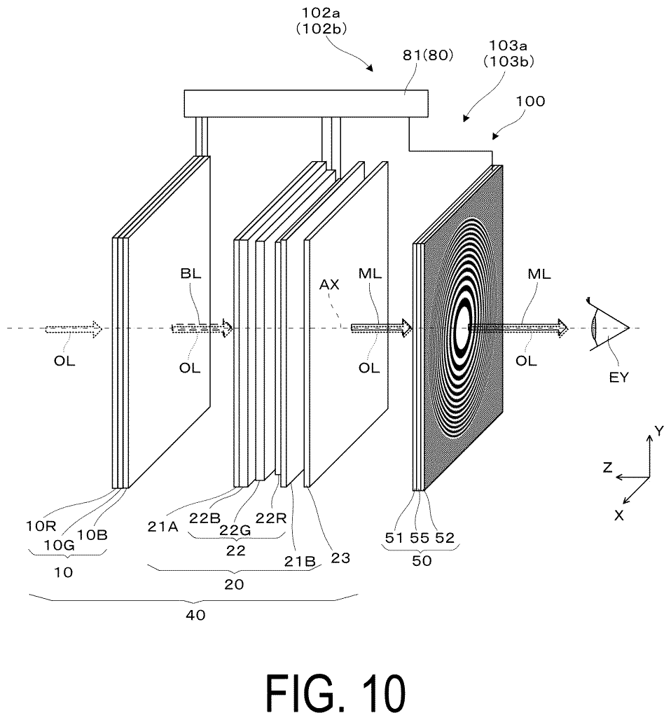

As illustrated in FIG. 10, the transmissive liquid crystal panel 22 of the display element 20 according to the present embodiment includes a first transmissive liquid crystal panel 22R, a second transmissive liquid crystal panel 22G, and a third transmissive liquid crystal panel 22B. The third transmissive liquid crystal panel 22B, the second transmissive liquid crystal panel 22G, and the first transmissive liquid crystal panel 22R are arranged so as to face each other in parallel in this order in the −Z direction toward the eye EY of the wearer US from the outside world.

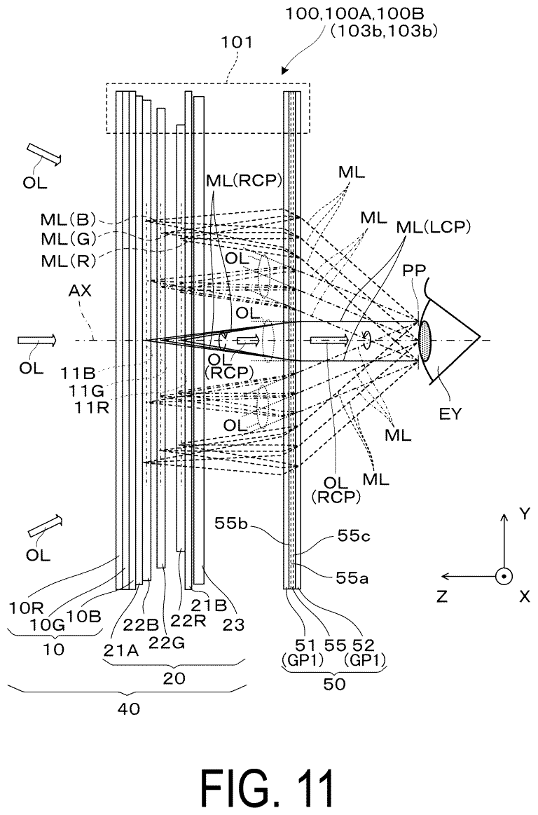

FIG. 11 is a side cross-sectional view illustrating the optical unit 100 of the display optical systems 103a and 103b. As illustrated in FIG. 11, the first light source 10R and the first transmissive liquid crystal panel 22R operate as a first image light emitting device configured to emit the first image light ML (R) representing the intensity distribution of the wavelength component of the first color of the image light ML. Similarly, the second light source 10G and the second transmissive liquid crystal panel 22G operate as a second image light emitting device configured to emit the second image light ML (G) representing the intensity distribution of the wavelength component of the second color of the image light ML. The third light source 10B and the third transmissive liquid crystal panel 22B operate as a third image light emitting device configured to emit the third image light ML (B) representing the intensity distribution of the wavelength component of the third color of the image light ML.

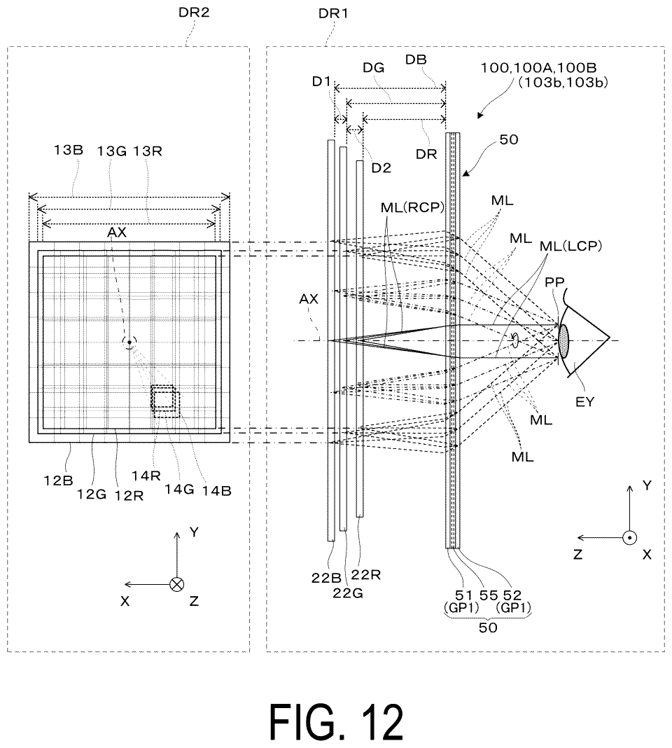

With reference to FIG. 12, correction of color aberration of the polarization diffraction lenses 51 and 52 by appropriately setting the distance from each of the transmissive liquid crystal panels 22R, 22G, and 22B to the first polarization diffraction lens 51 and appropriately setting the dimensions of pixels included in display regions 12R, 12G, and 12B of the transmissive liquid crystal panels 22R, 22G, and 22B, respectively, will be described.

One of the causes of generation of color aberration of the polarization diffraction lenses 51 and 52 is that the focal lengths of the polarization diffraction lenses 51 and 52 is different depending on the wavelength of the incident light. More specifically, in the polarization diffraction lenses 51 and 52, a focal length corresponding to light having a shorter wavelength is longer, and a focal length corresponding to light having a longer wavelength is shorter. In this manner, the wavelength dependency of the focal length in the polarization diffraction lenses 51 and 52 is opposite to the wavelength dependency of the focal length in a refraction lens. Therefore, in the present embodiment, in order to correct the color aberration of the polarization diffraction lenses 51 and 52, a distance DB between the transmissive liquid crystal panel 22B of the third color configured to emit light having a shorter wavelength, for example, the third image light ML (B) representing the intensity distribution of the wavelength component of blue of the image light ML, and the polarization diffraction lens 51 is set to be longer, and a distance DR between the transmissive liquid crystal panel 22R of the first color configured to emit light having a longer wavelength, for example, the first image light ML (R) representing the intensity distribution of the wavelength component of red of the image light ML, and the polarization diffraction lens 51 is set to be shorter. A distance DG between the transmissive liquid crystal panel 22G of the second color configured to emit light having an intermediate wavelength, for example, the second image light ML (G) representing the intensity distribution of the wavelength component of green of the image light ML, and the polarization diffraction lens 51 is set to an intermediate length.

Here, if the dimensions of the pixels in each of the transmissive liquid crystal panels 22R, 22G, and 22B are the same, when viewed from the eye EY of the wearer US, the pixels included in the display region 12B of the transmissive liquid crystal panel 22B of the third color having the longer distance DB from the polarization diffraction lenses 51 and 52 appear relatively small, and the pixels included in the display region 12R of the transmissive liquid crystal panel 22R of the first color having the shorter distance DR from the polarization diffraction lenses 51 and 52 appear relatively large. In order to correct this difference, in the present embodiment, the dimensions of pixels 14R, 14G, and 14B respectively included in the display regions 12R, 12G, and 12B of the transmissive liquid crystal panels 22R, 22G, and 22B are appropriately set according to the distance from each of the transmissive liquid crystal panels 22R, 22G, and 22B to the imaging optical system 50. More specifically, a dimension 13B of the display region 12B of the transmissive liquid crystal panel 22B of the third color having the longer distance DB from the polarization diffraction lenses 51 and 52 is set to be relatively large, and a dimension 13R of the display region 12R of the transmissive liquid crystal panel 22R of the first color having the shorter distance DR from the polarization diffraction lenses 51 and 52 is set to be relatively small. A dimension 13G of the display region 12G of the transmissive liquid crystal panel 22G of the second color having the intermediate distance DG from the polarization diffraction lenses 51 and 52 is set to be intermediate. As a result, the difference among the first dimension of the first pixel 14R included in the first transmissive liquid crystal panel 22R, the second dimension of the second pixel 14G included in the second transmissive liquid crystal panel 22G, and the third dimension of the third pixel 14B included in the third transmissive liquid crystal panel 22B offsets the difference among the distances of each of the first pixel 14R, the second pixel 14G, and the third pixel 14B to the first polarization diffraction lens. The first pixel 14R, the second pixel 14G, and the third pixel 14B corresponding to one another have shapes apparently overlapping one another at a desired observation position.

As an example, as illustrated in regions DR1 and DR2 of FIG. 12, when the transmissive liquid crystal panel 22R of the first color is brought closer to the polarization diffraction lens 51 by 2.3 mm with reference to the position and dimension of the transmissive liquid crystal panel 22G of the second color (when D2=2.3 mm in the region DR1), the dimension of the pixel included in the display region 12R of the transmissive liquid crystal panel 22R of the first color is reduced to 94% (set 13R/13G=94% in the region DR2). When the transmissive liquid crystal panel 22B of the third color is moved away from the polarization diffraction lens 51 by 1.6 mm (when D1=1.6 mm in the region DR1), the dimension of the pixel included in the transmissive liquid crystal panel 22B of the third color is enlarged to 111% (set 13B/13G=111% in the region DR2). At this time, when viewed from the eye EY of the wearer US, the pixels included in each of the transmissive liquid crystal panels 22R, 22G, and 22B apparently overlap each other in the same size, and the image quality of the image light ML can be improved.

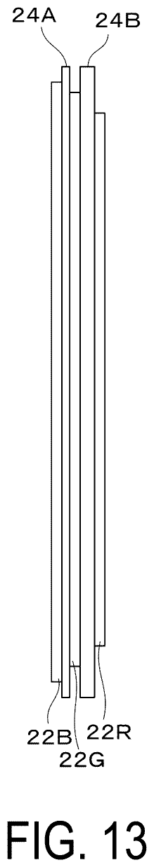

In order to stably keep the positional relationship among the transmissive liquid crystal panels 22R, 22G, and 22B, as illustrated in FIG. 13, spacers 24A and 24B having a transparent plate shape may be provided among the transmissive liquid crystal panels 22R, 22G, and 22B, and the transmissive liquid crystal panels 22R, 22G, and 22B and the spacers 24A and 24B may be fixed by gluing or the like. The spacers 24A and 24B may be made of glass or may be made of resin. In addition to the transmissive liquid crystal panels 22R, 22G, and 22B and the spacers 24A and 24B, some or all of the light sources 10R, 10G, and 10B, the polarization plates 21A and 21B, the quarter wavelength plate 23, and the imaging optical system 50 may be fixed and integrated.

A display operation by the display optical systems 103a and 103b according to the present embodiment will be described. The display operation by the display optical systems 103a and 103b according to the present embodiment can be obtained by changing the display operation according to the first embodiment described with reference to FIG. 9 as follows. That is, in the present embodiment, the transmissive liquid crystal panel 22R of the first color is driven by the first driving signal SM1 to form the first image light ML (R), the transmissive liquid crystal panel 22G of the second color is driven by the second driving signal SM2 to form the second image light ML (G), and the transmissive liquid crystal panel 22B of the third color is driven by the third driving signal SM3 to form the third image light ML (B). Other elements of the display operation by the display optical systems 103a and 103b according to the present embodiment are the same as those in the first embodiment.

In the present embodiment, in the first sub-frame ZR, the second light source 10G and the third light source 10B are in the transmission state of not emitting the backlights BLG, and BLB, and the transmissive liquid crystal panel 22G of the second color and the transmissive liquid crystal panel 22B of the third color are in the non-display state of not forming the image lights ML (G) and ML (B) and transmits the backlight BLR of the first color emitted by the first light source 10R. As a result, in the first sub-frame ZR, only the first image light ML (R) representing the intensity distribution of the wavelength component of the first color of the image light ML is displayed, and the second image light ML (G) representing the intensity distribution of the wavelength component of the second color and the third image light ML (B) representing the intensity distribution of the wavelength component of the third color are not displayed. Similarly, in the second sub-frame ZG, the first light source 10R is in the transmission state of not emitting the backlight BLR and transmits the backlight BLG of the second color emitted by the second light source 10G, the third light source 10B is in the transmission state of not emitting the backlight BLB, the transmissive liquid crystal panel 22R of the first color is in the non-display state of not forming the image light ML (R) and transmits the image light ML (G) formed by the transmissive liquid crystal panel 22G of the second color, and the transmissive liquid crystal panel 22B of the third color is in the non-display state of not forming the image light ML (B). As a result, in the second sub-frame ZG, only the second image light ML (G) representing the intensity distribution of the wavelength component of the second color of the image light ML is displayed, and the first image light ML (R) representing the intensity distribution of the wavelength component of the first color and the third image light ML (B) representing the intensity distribution of the wavelength component of the third color are not displayed. In the third sub-frame ZB, the first light source 10R and the second light source 10G are in the transmission state of not emitting the backlights BLR and BLG and transmit the backlight BLB of the third color emitted by the third light source 10B, and the transmissive liquid crystal panel 22R of the first color and the transmissive liquid crystal panel 22G of the second color are in the non-display state of not forming the image lights ML (R) and ML (G) and transmit the image light ML (B) formed by the transmissive liquid crystal panel 22B of the third color. As a result, in the third sub-frame ZB, only the third image light ML (B) representing the intensity distribution of the wavelength component of the third color of the image light ML is displayed, and the first image light ML (R) representing the intensity distribution of the wavelength component of the first color and the second image light ML (G) representing the intensity distribution of the wavelength component of the second color are not displayed.

When the first virtual image display device 100A is in the fourth sub-frame ZO as the outside light observation period, the light sources 10R, 10G, and 10B are in the transmission state of not emitting the backlights BLR, BLG, and BLB, the transmissive liquid crystal panels 22R, 22G, and 22B are in the non-display state, and the switching half-wavelength plate 55 is in the off state of transmitting light as it is, the external light OL transmits through the light sources 10R, 10G, and 10B, the transmissive liquid crystal panels 22R, 22G, and 22B, and the switching half-wavelength plate 55, and reaches the eye EY of the wearer US. In this manner, the first virtual image display device 100A repeats, in a sufficiently short cycle, the state of displaying the image light ML in the image observation period including the sub-frames ZR, ZG, and ZB and the state of transmitting the external light OL in the outside light observation period as the sub-frame ZO, thereby enabling see-through display in which the full-color image light ML and the external light OL are overlapped in time-division.

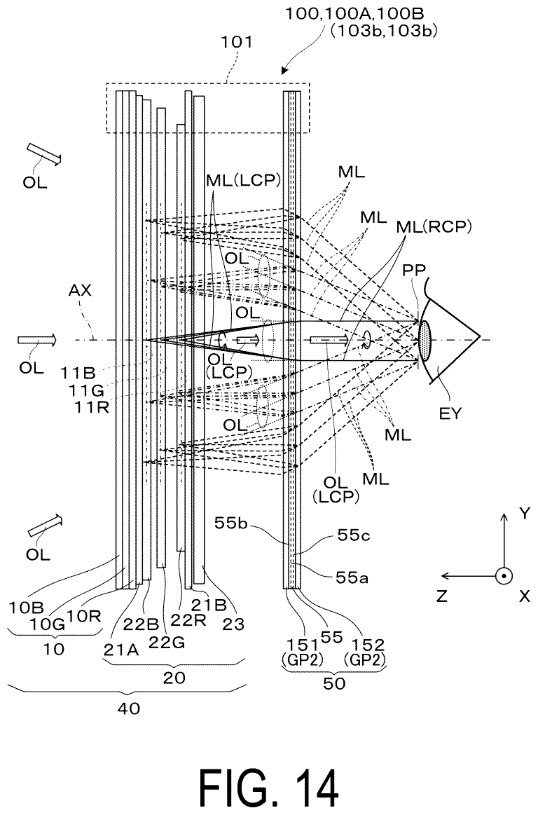

A modification of the present embodiment will be described with reference to FIG. 14. FIG. 14 is a view illustrating the display optical systems 103a and 103b of the modification, and corresponds to FIG. 11. In the configuration of FIG. 14, each of a first polarization diffraction lens 151 and a second polarization diffraction lens 152 as the polarization diffraction lens GP1 illustrated in FIG. 8 in the configuration of FIG. 11 is changed to the polarization diffraction lens GP2 illustrated in FIG. 8. In this case, the image light ML of the left circular polarization LCP is emitted from the display 40 in the previous stage of time-division, and the external light OL of the left circular polarization LCP is transmitted by the display 40 in the subsequent stage of time-division.

In the imaging optical system 50, the first polarization diffraction lens 151 and the second polarization diffraction lens 152 are the polarization diffraction lenses GP2 illustrated in the third region CR3 and the fourth region CR4 of FIG. 8, and when the image light ML and the external light OL incident from the display 40 are the left circular polarization LCP, function as optical elements having positive power with respect to the image light ML and the external light OL, and invert the rotation direction of polarization to the right circular polarization RCP while reducing the divergence degree of the image light ML and the external light OL.

In the case of the image observation period, the image light ML passed through the first polarization diffraction lens 151 is incident on the switching half-wavelength plate 55, returned to the left circular polarization LCP, and incident on the second polarization diffraction lens 152. As a result, the first polarization diffraction lens 151 and the second polarization diffraction lens 152 relatively converge the image light ML passing from the display 40 side, and change from the left circular polarization LCP that is the first circular polarization to the right circular polarization RCP that is the second circular polarization. In this case, the imaging optical system 50 is in a state of having positive power, and therefore the image light ML can be observed.

On the other hand, in the case of the outside light observation period, the external light OL passed through the first polarization diffraction lens 151 is incident on the switching half-wavelength plate 55, is maintained as the right circular polarization RCP as it is, and is incident on the second polarization diffraction lens 152. As a result, the first polarization diffraction lens 151 and the second polarization diffraction lens 152 cause the external light OL passing from the display 40 side to travel substantially straight and maintain the left circular polarization LCP as it is that is the first circular polarization. In this case, the imaging optical system 50 is in a state of having no power, and therefore the external light OL can be observed.

Note that the modification illustrated in FIG. 14 is also applicable to the first embodiment.

In the virtual image display devices 100A and 100B or the optical unit 100 according to the present embodiment described above, even when the first color component, the second color component, and the third color component of the image light ML are formed by the three transmissive liquid crystal panels 22R, 22G, and 22B, respectively, color aberration in the polarization diffraction lenses 51 and 52 included in the imaging optical system 50 can be corrected by arranging each of the transmissive liquid crystal panels 22R, 22G, and 22B at different appropriate distances from the imaging optical system 50.

### Third Embodiment

In the first embodiment and the second embodiment described above, the configurations of the virtual image display devices 100A and 100B and the optical unit 100 using the transmissive liquid crystal panel 22 including no color filter have been described. In the present embodiment, configurations of the virtual image display devices 100A and 100B and the optical unit 100 using the transmissive liquid crystal panel 22 including a color filter will be described.

When the transmissive liquid crystal panel 22 includes a color filter, it is possible to simultaneously emit the first image light ML (R) of the first color, the second image light ML (G) of the second color, and the third image light ML (B) of the third color of the image light ML. At this time, of the light source member 10, the first light source 10R, the second light source 10G, and the third light source 10B can simultaneously emit the backlight BLR of the first color, the backlight BLG of the second color, and the backlight BLB of the third color, respectively. As a result, in the virtual image display devices 100A and 100B and the optical unit 100 according to the present embodiment, the ratio of the image light ML and the external light OL to be overlapped in time-division can be selected from a wider range.

The configurations of the virtual image display devices 100A and 100B and the optical unit 100 according to the present embodiment are partially modified from the configuration according to the first embodiment. In the configurations of the virtual image display devices 100A and 100B and the optical unit 100 according to the present embodiment, description of parts common to the configurations according to the first embodiment may be omitted.

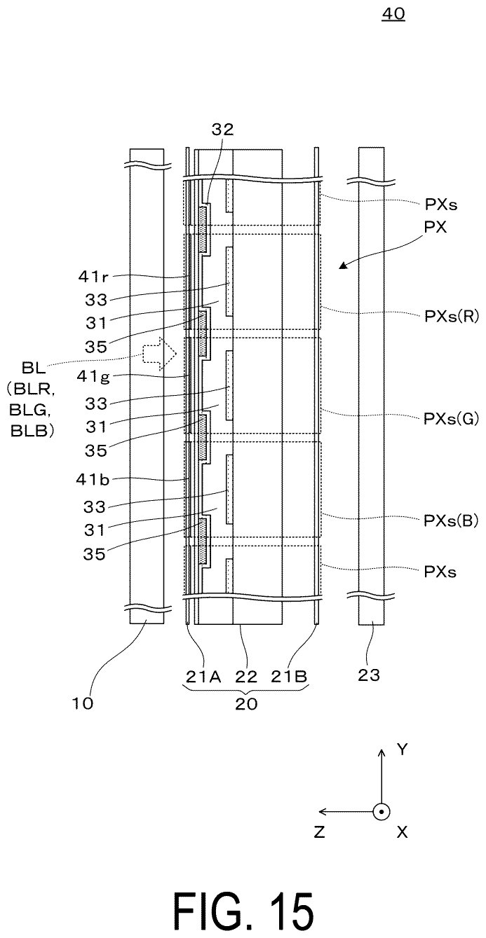

As illustrated in FIG. 15, the display element 20 according to the present embodiment includes a color filter 41r of the first color, a color filter 41g of the second color, and a color filter 41b of the third color in addition to the components included in the display element 20 according to the first embodiment illustrated in FIG. 4. Each of the plurality of pixels PX included in the display element 20 according to the present embodiment includes a sub-pixel PXs (R) of the first color, a sub-pixel PXs (G) of the second color, and a sub-pixel PXs (B) of the third color. Here, the sub-pixel PXs (R) of the first color includes the color filter 41r of the first color, the sub-pixel PXs (G) of the second color includes the color filter 41g of the second color, and the sub-pixel PXs (B) of the third color includes the color filter 41b of the third color.

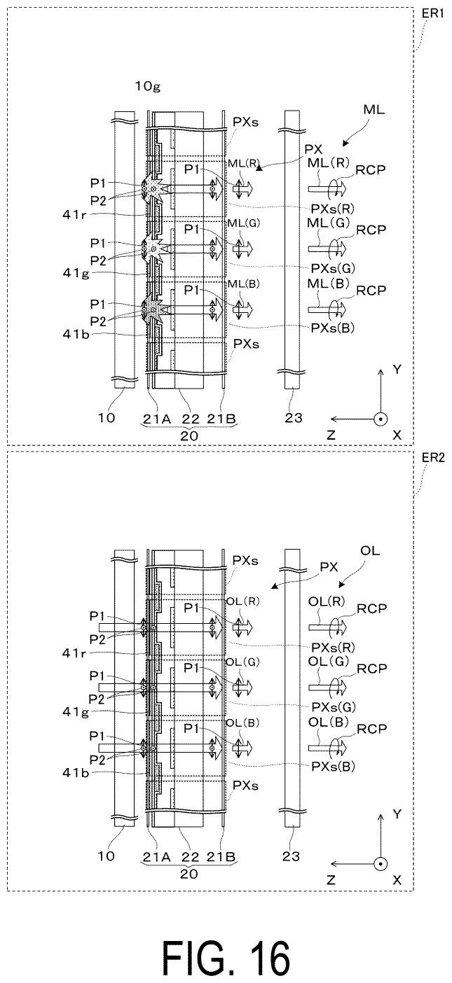

With reference to FIG. 16, a state of light passing through the display 40 according to the present embodiment will be described. In FIG. 16, a first region ER1 indicates a case where the first display optical system 103a is in the image observation period and the display 40 is in the display state, and a second region ER2 indicates a case where the first display optical system 103a is in the outside light observation period and the display 40 is in the non-display state.

As illustrated in the first region ER1 of FIG. 16, when the display 40 is in the display state in the image observation period, the light source member 10 emits the backlight BL toward the display element 20. More specifically, of the light source member 10, the light-emitting layers 104R, 104G, and 104B illustrated in FIG. 3 simultaneously emit the backlights BLR, BLG, and BLB toward the display element 20.

The backlight BLR of the first color passes through the color filter 41r of the first color and reaches the sub-pixel PXs (R) of the first color, but is blocked by the color filters 41g and 41b of the second color and the third color and does not reach the sub-pixels PXs (G) and PXs (B) of the second color and the third color. Similarly, the backlight BLG of the second color passes through the color filter 41g of the second color and reaches the sub-pixel PXs (G) of the second color, but is blocked by the color filters 41r and 41b of the first color and the third color and does not reach the sub-pixels PXs (R) and PXs (B) of the first color and the third color. The backlight BLB of the third color passes through the color filter 41b of the third color and reaches the sub-pixel PXs (B) of the third color, but is blocked by the color filters 41r and 41g of the first color and the second color and does not reach the sub-pixels PXs (R) and PXs (G) of the first color and the second color.

The sub-pixel PXs (R) of the first color forms the first image of the first color component of the image. The backlight BLR of the first color passes through the sub-pixel of the first color in a state of forming the first image, whereby the light-emitting layer 104R of the first color and the sub-pixel PXs (R) of the first color emit the first image light ML (R) of the first color component of the image light ML. Similarly, the sub-pixel PXs (G) of the second color forms the second image of the second color component of the image. The backlight BLG of the second color passes through the sub-pixel of the second color in a state of forming the second image, whereby the light-emitting layer 104G of the second color and the sub-pixel PXs (G) of the second color emit the second image light ML (G) of the second color component of the image light ML. The sub-pixel PXs (B) of the third color forms the third image of the third color component of the image. The backlight BLB of the third color passes through the sub-pixel of the third color in a state of forming the third image, whereby the light-emitting layer 104B of the third color and the sub-pixel PXs (B) of the third color emit the third image light ML (B) of the third color component of the image light ML.

As illustrated in the second region ER2 of FIG. 16, when the display 40 is in the non-display state in the outside light observation period, the light source member 10 is brought into the non-light emission state, that is, the light off state. At this time, each of the light source member 10 and the sub-pixels PXs (R), PXs (G), and PXs (B) of the display element 20 is in the maximum transmission state. At this timing, the external light OL passes through the light source member 10 and is incident on the display element 20. Of the external light OL incident on the display element 20, first external light OL (R) passed through the color filter 41r of the first color, second external light OL (G) passed through the color filter 41g of the second color, and third external light OL (B) passed through the color filter 41b of the third color further pass through the sub-pixels PXs (R), PXs (G), and PXs (B) and the quarter wavelength plate 23, thereby reaching the eye EY of the wearer US.

Note that the polarization plates 21A and 21B, the quarter wavelength plate 23, and the changes in polarization of the backlights BLR, BLG, and BLB, the image lights ML (R), ML (G), and ML (B), and the external lights OL, OL (R), OL (G), and OL (B) are the same as those in the first embodiment described with reference to FIG. 5.

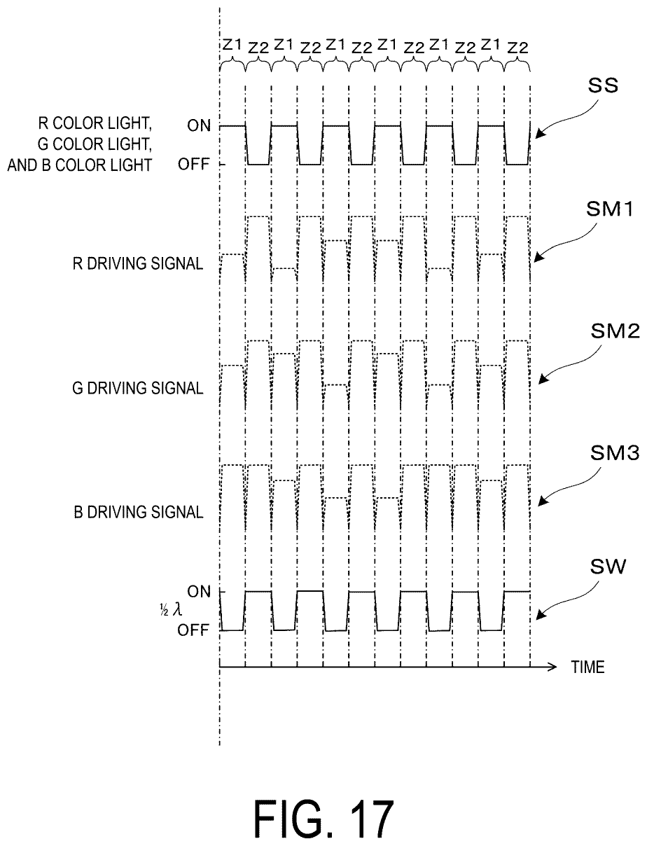

A display operation by the display optical systems 103a and 103b according to the present embodiment will be described with reference to FIG. 17. In the timing chart of FIG. 17, the horizontal axis represents time, and examples of waveforms of the blinking signal SS of each of the light sources 10R, 10G, and 10B of the light source member 10, the first driving signal SM1 of the first color component display, the second driving signal SM2 of the second color component display, and the third driving signal SM3 of the third color component display of the transmissive liquid crystal panel 22, and the on-off signal SW of the switching half-wavelength plate 55 are illustrated in order from the top.

When the first virtual image display device 100A is in a first sub-frame Z1 for image observation, the first light source 10R, the second light source 10G, and the third light source 10B of the light source member 10 emit the backlight BLR of the first color, the backlight BLG of the second color, and the backlight BLB of the third color, respectively. When the first virtual image display device 100A is in the first sub-frame Z1 for image observation, the sub-pixel PXs (R) of the first color, the sub-pixel PXs (G) of the second color, and the sub-pixel PXs (B) of the third color of the transmissive liquid crystal panel 22 respectively display the first image light ML (R) representing the intensity distribution of the wavelength component of the first color, the second image light ML (G) representing the intensity distribution of the wavelength component of the second color, and the third image light ML (B) representing the intensity distribution of the wavelength component of the third color of the image light ML. As a result, when in the first sub-frame Z1 for image observation, the first virtual image display device 100A simultaneously displays the first image light ML (R), the second image light ML (G), and the third image light ML (B) constituting the image light ML.

When the first virtual image display device 100A is in a second sub-frame Z2 as the outside light observation period, the first light source 10R, the second light source 10G, and the third light source 10B of the light source member 10 are in the transmission state of not emitting the backlights BLR, BLG, and BLB, respectively, the sub-pixels PXs (R), PSx (G), and PXs (B) of the transmissive liquid crystal panel 22 are in the non-display state, and the switching half-wavelength plate 55 is in the off state of transmitting light as it is. Therefore, when the first virtual image display device 100A is in the second sub-frame Z2 as the outside light observation period, the external light OL reaches the eye EY of the wearer US as the external lights OL (R), OL (G), and OL (B) passed through the color filters 41r, 41g, and 41b.

The first virtual image display device 100A according to the present embodiment repeats the first sub-frame Z1 and the second sub-frame Z2 in a sufficiently short cycle, thereby enabling see-through display in which the full-color image light ML and the external light OL are overlapped in time-division.

In the virtual image display devices 100A and 100B and the optical unit 100 according to the present embodiment, in addition to the actions and effects of the virtual image display devices 100A and 100B and the optical unit 100 according to the first embodiment, the ratio of the image light ML and the external light OL to be overlapped in time-division can be selected from a wider range.

### Modifications

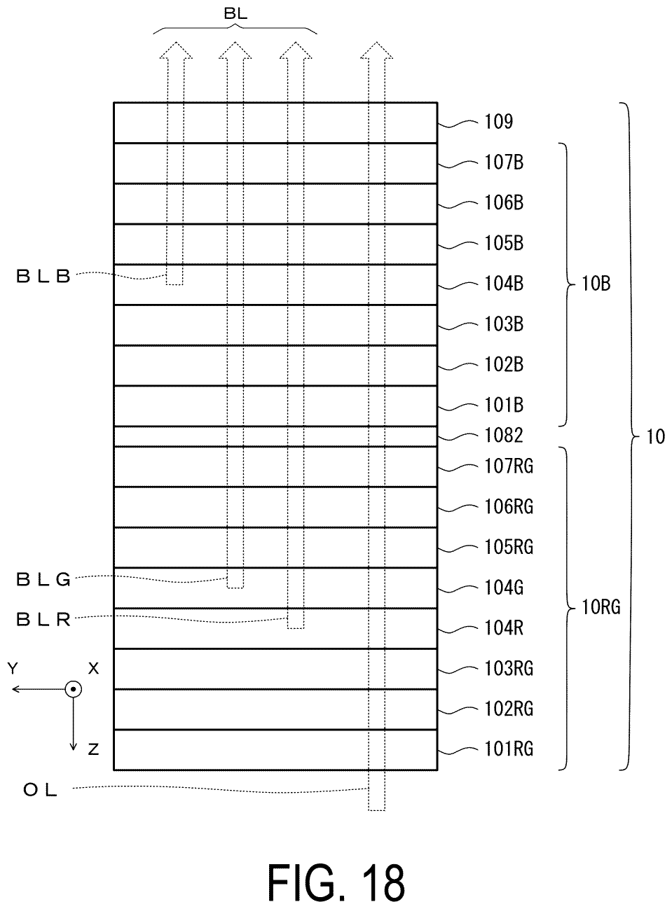

In the third embodiment described above, as illustrated in FIG. 3, the configuration in which the first light source 10R, the second light source 10G, and the third light source 10B of the light source member 10 are separately stacked has been described. As a modification of this configuration, as illustrated in FIG. 18, a fourth light source 10RG in which the first light source 10R and the second light source 10G of FIG. 3 are integrated may be provided. The cross-sectional view of FIG. 18 is obtained by adding the following changes to the cross-sectional view of FIG. 3. That is, the first light source 10R and the first adhesive layer 1081 are removed, and the second light source 10G is replaced with the fourth light source 10RG. A fourth transparent substrate 101RG, a fourth transparent anode 102RG, a fourth hole transport layer 103RG, the first light-emitting layer 104R, the second light-emitting layer 104G, a fourth electron transport layer 105RG, a fourth transparent cathode 106RG, and a first sealing layer 107RG included in a fourth light source 10RG are stacked in this order in the −Z direction in the Cartesian coordinate system.

In the fourth light source 10RG, when an appropriate voltage is applied between the fourth transparent anode 102RG and the fourth transparent cathode 106RG, the first light-emitting layer 104R emits the backlight BLR of the first color, and the second light-emitting layer 104G emits the backlight BLG of the second color.

Other configurations and operations of the light source member 10 are similar to those of the third embodiment illustrated in FIG. 3. Other configurations and operations of the virtual image display devices 100A and 100B and the optical unit 100 according to the present modification are the same as those in the third embodiment.

According to the present modification, in addition to the actions and effects of the third embodiment, the light source member 10 can be further downsized.

Although it has been assumed above that the HMD 200 is worn on the head and is used, the virtual image display devices 100A and 100B may also be used as a hand-held display that is not worn on the head and is to be looked into like binoculars. That is, according to an aspect of the present disclosure, the head-mounted display also includes a hand-held display.

A virtual image display device in a specific aspect includes: a transmissive organic light emitting diode (OLED) panel configured to transmit external light in a first state and emit backlight in a second state, a display element of a transmissive type facing the transmissive OLED panel, and configured to further transmit the external light passed through the transmissive OLED panel in the first state and transmit the backlight emitted from the transmissive OLED panel in the second state to emit image light, and an imaging optical system facing the transmissive OLED panel with the display element in between, and configured to transmit at least part of the external light in the first state and form an image with the image light in the second state, in which the transmissive OLED panel includes a first transmissive OLED element configured to emit light of a first color, and a second transmissive OLED element stacked on the first transmissive OLED element and configured to emit light of a second color.

A virtual image display device in a specific aspect further includes a control device configured to switch between the first state and the second state by controlling the transmissive OLED panel, the display element, and the imaging optical system.

The virtual image display device achieves uniformity of backlight, low power consumption, and downsizing of the light source member by adopting the transmissive OLED panel as a light source member configured to emit the backlight.

In a virtual image display device in a specific aspect, the transmissive OLED panel further includes a third transmissive OLED element stacked on the second transmissive OLED element and configured to emit light of a third color, the transmissive OLED panel emits light of the first color in the second state, emits light of the second color in a third state, and emits light of the third color in a fourth state, the display element displays an image of the image light by transmitting light emitted from the transmissive OLED panel in the third state and the fourth state, the imaging optical system forms the image in the third state and the fourth state, and the control device further switches between the third state and the fourth state by controlling the transmissive OLED panel, the display element, and the optical system.

In the virtual image display device, the light source member emits backlight of three colors in time-division, and the display element displays, in time-division, image light representing the intensity distribution of wavelength components of the three colors of the image light.

In a virtual image display device in a specific aspect, the display element includes a transmissive liquid crystal panel configured to display, while switching in time-division, a first image representing an intensity distribution of a wavelength component of the first color, a second image representing an intensity distribution of a wavelength component of the second color, and a third image representing an intensity distribution of a wavelength component of the third color in the image, and the transmissive liquid crystal panel displays the first image of the image in the second state, displays the second image of the image in the third state, and displays the third image of the image in the fourth state.

In the virtual image display device, a single transmissive liquid crystal panel can be adopted as a display element.

In a virtual image display device in a specific aspect, the display element includes a first transmissive liquid crystal panel configured to display a first image representing an intensity distribution of a wavelength component of the first color of the image in the second state, a second transmissive liquid crystal panel facing the first transmissive liquid crystal panel and configured to display a second image representing an intensity distribution of a wavelength component of the second color of the image in the third state, and a third transmissive liquid crystal panel facing the second transmissive liquid crystal panel and configured to display a third image representing an intensity distribution of a wavelength component of the third color of the image in the fourth state.

In the virtual image display device, three transmissive liquid crystal panels can be adopted as display elements.

In a virtual image display device in a specific aspect, the transmissive OLED panel further includes a third transmissive OLED element stacked on the second transmissive OLED element and configured to emit light of a third color, in the second state, the first transmissive OLED element, the second transmissive OLED element, and the third transmissive OLED element simultaneously emit light, the display element includes a transmissive liquid crystal panel including a plurality of pixels arrayed in a matrix, and each of the plurality of pixels includes a first color filter configured to selectively transmit light of the first color, a first sub-pixel facing the first color filter and configured to display a first image representing an intensity distribution of a wavelength component of the first color of an image of the image light, a second color filter configured to selectively transmit light of the second color, a second sub-pixel facing the second color filter and configured to display a second image representing an intensity distribution of a wavelength component of the second color of the image, a third color filter configured to selectively transmit light of the third color, and a third sub-pixel facing the third color filter and configured to display a third image representing an intensity distribution of a wavelength component of the third color of the image.

In the virtual image display device, one transmissive liquid crystal panel including three color filters can be adopted as a display element.

In a virtual image display device in a specific aspect, in the second state, the first transmissive OLED element emits light of the first color, and the second transmissive OLED element emits light of the second color and light of the third color, the display element includes a transmissive liquid crystal panel including a plurality of pixels arrayed in a matrix, each of the plurality of pixels includes a first color filter configured to selectively transmit light of the first color, a first sub-pixel facing the first color filter and configured to display a first image representing an intensity distribution of a wavelength component of the first color of an image of the image light, a second color filter configured to selectively transmit light of the second color, a second sub-pixel facing the second color filter and configured to display a second image representing an intensity distribution of a wavelength component of the second color of the image, a third color filter configured to selectively transmit light of the third color, and a third sub-pixel facing the third color filter and configured to display a third image representing an intensity distribution of a wavelength component of the third color of the image, and in the second state, the first sub-pixel, the second sub-pixel, and the third sub-pixel display the first image, the second image, and the third image, respectively.

In the virtual image display device, as a light source member, a configuration including the first transmissive OLED element configured to emit backlight of one color and the second transmissive OLED element configured to emit backlight of two colors can be adopted.

In a virtual image display device in a specific aspect, the imaging optical system includes a first polarization diffraction lens facing the transmissive liquid crystal panel and configured to have positive power with respect to first image light of the first image and second image light of the second image, the first image light and the second image light having circular polarization, a second polarization diffraction lens facing the transmissive liquid crystal panel with the first polarization diffraction lens in between, and configured to have positive power with respect to the first image light and the second image light that are incident through the first polarization diffraction lens and have circular polarization, and a switching half-wavelength plate arranged between the first polarization diffraction lens and the second polarization diffraction lens, and configured to offset power of the first polarization diffraction lens and the second polarization diffraction lens by functioning as a half-wavelength plate in the first state and cause both the first polarization diffraction lens and the second polarization diffraction lens to function as positive lenses by turning off the function in the second state, and the control device switches between the first state and the second state by further controlling the switching half-wavelength plate.

In the virtual image display device, the two polarization diffraction lenses are both configured to have positive power with respect to the image light, and it is possible to achieve an imaging optical system relatively thin and having a relatively short focal length.

A virtual image display device in a specific aspect includes: a first polarization diffraction lens facing the first transmissive liquid crystal panel and the second transmissive liquid crystal panel and configured to have positive power with respect to first image light of the first image and second image light of the second image, the first image light and the second image light having circular polarization, a second polarization diffraction lens facing the first transmissive liquid crystal panel and the second transmissive liquid crystal panel with the first polarization diffraction lens in between, and configured to have positive power with respect to the first image light and the second image light that are incident through the first polarization diffraction lens and have circular polarization, and a switching half-wavelength plate arranged between the first polarization diffraction lens and the second polarization diffraction lens, and configured to offset power of the first polarization diffraction lens and the second polarization diffraction lens by functioning as a half-wavelength plate in the first state and cause both the first polarization diffraction lens and the second polarization diffraction lens to function as positive lenses by turning off the function in the second state, in which the control device switches between the first state and the second state by further controlling the switching half-wavelength plate, a first wavelength of the first color is shorter than a second wavelength of the second color, and a first dimension of each of a plurality of first pixels included in the first transmissive liquid crystal panel is larger than a second dimension of each of a plurality of second pixels included in the second transmissive liquid crystal panel.

In the virtual image display device, the two polarization diffraction lenses are both configured to have positive power with respect to the image light, and it is possible to achieve an imaging optical system relatively thin and having a relatively short focal length. Color aberration of the polarization diffraction lens can be corrected by using the image light emitting device having a different distance from the polarization diffraction lens for each color component of the image light.

An optical unit in a specific aspect includes: a transmissive OLED panel configured to transmit external light in a first state and emit backlight in a second state, a display element of a transmissive type facing the transmissive OLED panel, and configured to further transmit the external light passed through the transmissive OLED panel in the first state and transmit the backlight emitted from the transmissive OLED panel in the second state to emit image light, and an imaging optical system facing the transmissive OLED panel with the display element in between, and configured to transmit at least part of the external light in the first state and form an image with the image light in the second state, in which the transmissive OLED panel includes a first transmissive OLED element configured to emit light of a first color, and a second transmissive OLED element stacked on the first transmissive OLED element and configured to emit light of a second color.

The optical unit achieves uniformity of backlight, low power consumption, and downsizing of the light source member by adopting the transmissive OLED panel as a light source member configured to emit the backlight.

What is claimed is:

1. A virtual image display device, comprising:
a transmissive organic light emitting diode (OLED) panel configured to transmit external light in a first state and emit backlight in a second state;
a display element of a transmissive type facing the transmissive OLED panel, and configured to further transmit the external light passed through the transmissive OLED panel in the first state and transmit the backlight emitted from the transmissive OLED panel in the second state to emit image light; and
an imaging optical system facing the transmissive OLED panel with the display element in between, and configured to transmit at least part of the external light in the first state and form an image with the image light in the second state, wherein
the transmissive OLED panel includes
a first transmissive OLED element configured to emit light of a first color, and
a second transmissive OLED element stacked on the first transmissive OLED element and configured to emit light of a second color.

2. The virtual image display device according to claim 1, further comprising:
a control device configured to switch between the first state and the second state by controlling the transmissive OLED panel, the display element, and the imaging optical system.

3. The virtual image display device according to claim 2, wherein
the transmissive OLED panel further includes
a third transmissive OLED element stacked on the second transmissive OLED element and configured to emit light of a third color,
the transmissive OLED panel emits light of the first color in the second state, emits light of the second color in a third state, and emits light of the third color in a fourth state,
the display element displays an image of the image light by transmitting light emitted from the transmissive OLED panel in the third state and the fourth state,
the imaging optical system forms the image in the third state and the fourth state, and
the control device further switches between the third state and the fourth state by controlling the transmissive OLED panel, the display element, and the imaging optical system.

4. The virtual image display device according to claim 3, wherein
the display element includes
a transmissive liquid crystal panel configured to display, while switching in time-division, a first image representing an intensity distribution of a wavelength component of the first color, a second image representing an intensity distribution of a wavelength component of the second color, and a third image representing an intensity distribution of a wavelength component of the third color in the image, and
the transmissive liquid crystal panel
displays the first image of the image in the second state,
displays the second image of the image in the third state, and
displays the third image of the image in the fourth state.

5. The virtual image display device according to claim 3, wherein
the display element includes
a first transmissive liquid crystal panel configured to display a first image representing an intensity distribution of a wavelength component of the first color of the image in the second state,
a second transmissive liquid crystal panel facing the first transmissive liquid crystal panel and configured to display a second image representing an intensity distribution of a wavelength component of the second color of the image in the third state, and
a third transmissive liquid crystal panel facing the second transmissive liquid crystal panel and configured to display a third image representing an intensity distribution of a wavelength component of the third color of the image in the fourth state.

6. The virtual image display device according to claim 2, wherein
the transmissive OLED panel further includes
a third transmissive OLED element stacked on the second transmissive OLED element and configured to emit light of a third color,
in the second state, the first transmissive OLED element, the second transmissive OLED element, and the third transmissive OLED element simultaneously emit light,
the display element includes
a transmissive liquid crystal panel including a plurality of pixels arrayed in a matrix, and
each of the plurality of pixels includes
a first color filter configured to selectively transmit light of the first color,
a first sub-pixel facing the first color filter and configured to display a first image representing an intensity distribution of a wavelength component of the first color of an image of the image light,
a second color filter configured to selectively transmit light of the second color,
a second sub-pixel facing the second color filter and configured to display a second image representing an intensity distribution of a wavelength component of the second color of the image,
a third color filter configured to selectively transmit light of the third color, and
a third sub-pixel facing the third color filter and configured to display a third image representing an intensity distribution of a wavelength component of the third color of the image.

7. The virtual image display device according to claim 2, wherein
in the second state, the first transmissive OLED element emits light of the first color, and the second transmissive OLED element emits light of the second color and light of the third color,
the display element includes
a transmissive liquid crystal panel including a plurality of pixels arrayed in a matrix,
each of the plurality of pixels includes
a first color filter configured to selectively transmit light of the first color,
a first sub-pixel facing the first color filter and configured to display a first image representing an intensity distribution of a wavelength component of the first color of an image of the image light,
a second color filter configured to selectively transmit light of the second color,
a second sub-pixel facing the second color filter and configured to display a second image representing an intensity distribution of a wavelength component of the second color of the image,
a third color filter configured to selectively transmit light of the third color, and
a third sub-pixel facing the third color filter and configured to display a third image representing an intensity distribution of a wavelength component of the third color of the image, and
in the second state, the first sub-pixel, the second sub-pixel, and the third sub-pixel display the first image, the second image, and the third image, respectively.

8. The virtual image display device according to claim 4, wherein
the imaging optical system includes
a first polarization diffraction lens facing the transmissive liquid crystal panel and configured to have positive power with respect to first image light of the first image and second image light of the second image, the first image light and the second image light having circular polarization,
a second polarization diffraction lens facing the transmissive liquid crystal panel with the first polarization diffraction lens in between, and configured to have positive power with respect to the first image light and the second image light that are incident through the first polarization diffraction lens and have circular polarization, and
a switching half-wavelength plate arranged between the first polarization diffraction lens and the second polarization diffraction lens, and configured to offset power of the first polarization diffraction lens and the second polarization diffraction lens by functioning as a half-wavelength plate in the first state and cause both the first polarization diffraction lens and the second polarization diffraction lens to function as positive lenses by turning off the function in the second state, and
the control device switches between the first state and the second state by further controlling the switching half-wavelength plate.

9. The virtual image display device according to claim 5, wherein
the imaging optical system includes
a first polarization diffraction lens facing the first transmissive liquid crystal panel and the second transmissive liquid crystal panel and configured to have positive power with respect to first image light of the first image and second image light of the second image, the first image light and the second image light having circular polarization,
a second polarization diffraction lens facing the first transmissive liquid crystal panel and the second transmissive liquid crystal panel with the first polarization diffraction lens in between, and configured to have positive power with respect to the first image light and the second image light that are incident through the first polarization diffraction lens and have circular polarization, and
a switching half-wavelength plate arranged between the first polarization diffraction lens and the second polarization diffraction lens, and configured to offset power of the first polarization diffraction lens and the second polarization diffraction lens by functioning as a half-wavelength plate in the first state and cause both the first polarization diffraction lens and the second polarization diffraction lens to function as positive lenses by turning off the function in the second state,
the control device switches between the first state and the second state by further controlling the switching half-wavelength plate,
a first wavelength of the first color is shorter than a second wavelength of the second color, and
a first dimension of each of a plurality of first pixels included in the first transmissive liquid crystal panel is larger than a second dimension of each of a plurality of second pixels included in the second transmissive liquid crystal panel.

10. An optical unit, comprising:
a transmissive OLED panel configured to transmit external light in a first state and emit backlight in a second state;
a display element of a transmissive type facing the transmissive OLED panel, and configured to further transmit the external light passed through the transmissive OLED panel in the first state and transmit the backlight emitted from the transmissive OLED panel in the second state to emit image light; and
an imaging optical system facing the transmissive OLED panel with the display element in between, and configured to transmit at least part of the external light in the first state and form an image with the image light in the second state, wherein
the transmissive OLED panel includes
a first transmissive OLED element configured to emit light of a first color, and
a second transmissive OLED element stacked on the first transmissive OLED element and configured to emit light of a second color.
